(19) United States
(12) Patent Application Publication
(10) Pub. No.: US 2026/0215095 A1
(43) Pub. Date: Jul. 23, 2026

(54) DISPLAY DEVICE, ELECTRONIC DEVICE AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(21) Appl. No.: 19/391,423

(22) Filed: Nov. 17, 2025

(30) Foreign Application Priority Data
Jan. 22, 2025 (KR) 10-2025-0009337

(51) Int. Cl. H10K 59/122; H10K 59/12; H10K 59/80; H10K 59/88; H10K 50/19

(52) U.S. Cl. CPC H10K 59/122; H10K 59/1201; H10K 59/80516; H10K 59/873; H10K 59/88; H10K 50/19

(57) ABSTRACT

The present disclosure relates to a display device capable of improving image quality by minimizing or reducing lateral and vertical leakage current, an electronic device including the display device, and a method for fabricating a display device. The display device may include: a substrate; a reflective electrode on the substrate; an optical auxiliary layer on the reflective electrode; a first electrode on the optical auxiliary layer; a light emitting stack on the first electrode; a second electrode on the light emitting stack; a pixel defining layer arranged on an edge of the first electrode and defining a light emitting area; a planarization layer on the pixel defining layer; and a spacer protruding on the planarization layer, wherein the light emitting stack is disconnected along the spacer.

### CROSS-REFERENCE TO RELATED APPLICATION

This application claims priority to and the benefit of Korean Patent Application No. 10-2025-0009337 filed on January 22, 2025, in the Korean Intellectual Property Office, the entire content of which is incorporated herein by reference.

### BACKGROUND

### 1. Field

One or more embodiments of the present disclosure relate to a display device, and for example, to a display device capable of improving image quality by minimizing or reducing lateral and vertical leakage current, an electronic device including such a display devise, and a method for fabricating such a display device.

### 2. Description of the Related Art

A head mounted display (HMD) is an image display device that is worn on a user’s head in the form of glasses or a helmet and is designed to focus images at a distance close to user’s eyes. HMDs may be utilized to implement (realize) virtual reality (VR) or augmented reality (AR) experiences.

A head mounted display enlarges/magnifies and displays images from a small display panel (device) using a plurality of lenses. Accordingly, the display panel (device) utilized in an HMD is required or desired to be capable of providing high-resolution images, for example, with a resolution of about 3000 pixels per inch (PPI) or higher. To meet this requirement or desire, an organic light emitting diode on silicon (OLEDoS) display—a high-resolution, small-sized organic light-emitting display device—may be employed. OLEDoS displays are configured by arranging organic light emitting diodes (OLEDs) on a semiconductor wafer substrate that includes a complementary metal oxide semiconductor (CMOS) circuit.

### SUMMARY

One or more aspects of embodiments of the present disclosure are directed toward a display device capable of improving image quality by minimizing or reducing lateral and vertical leakage current, an electronic device including the display device, and a method for fabricating a display device. Additional aspects will be set forth in part in the description which follows and, in part, will be apparent from the description, or may be learned by practice of the presented embodiments of the disclosure.

According to one or more embodiments of the present disclosure, a display device includes: a substrate; a reflective electrode on the substrate; an optical auxiliary layer on the reflective electrode; a first electrode on the optical auxiliary layer; a light emitting stack on the first electrode; a second electrode on the light emitting stack; a pixel defining layer on (e.g., arranged on) an edge of the first electrode and defining a light emitting area; a planarization layer on the pixel defining layer; and a spacer protruding on the planarization layer, wherein the light emitting stack is disconnected along the spacer (e.g., disconnected from a neighboring light emitting stack along the spacer).

According to one or more embodiments of the present disclosure, an electronic device includes: a display device including (e.g., providing) a screen, wherein the display device includes: a substrate; a reflective electrode on the substrate; an optical auxiliary layer on the reflective electrode; a first electrode on the optical auxiliary layer; a light emitting stack on the first electrode; a second electrode on the light emitting stack; a pixel defining layer on (e.g., arranged on) an edge of the first electrode and defining a light emitting area; a planarization layer on the pixel defining layer; and a spacer protruding on the planarization layer, wherein the light emitting stack is disconnected along the spacer (e.g., disconnected from a neighboring light emitting stack along the spacer).

According to one or more embodiments of the present disclosure, there is provided a method for fabricating a display device, the method including: forming a reflective electrode on a substrate; forming an optical auxiliary layer on the reflective electrode; forming a first electrode on the optical auxiliary layer; forming a pixel defining layer defining a light emitting area on an edge of the first electrode; forming a planarization layer on the pixel defining layer; forming a spacer on the planarization layer; forming a sacrificial layer including a material different from the spacer on the spacer so as to overlap the spacer; forming a light emitting stack on the first electrode, the pixel defining layer, the planarization layer, and the sacrificial layer; forming a second electrode on the light emitting stack; forming a first encapsulation layer on the second electrode; and disconnecting the light emitting stack, the second electrode, and the first encapsulation layer on the sacrificial layer along the spacer by removing the sacrificial layer.

According to one or more embodiments of the present disclosure, the image quality of the display device and the electronic device may be improved by minimizing or reducing the lateral and vertical leakage current.

For example, according to one or more embodiments, because the light emitting stack may be disconnected for each sub-pixel by the spacer protruding toward the encapsulation layer on the planarization layer, leakage current between adjacent sub-pixels (e.g., lateral leakage current) may be minimized or reduced, thereby preventing or reducing a color mixing phenomenon between the adjacent sub-pixels. In addition, if (e.g., when) the light emitting stack is disconnected through an existing trench, the leakage current (e.g., vertical leakage current) due to the gap reduction between charge generation layers within the trench may be minimized or reduced, thereby preventing or reducing the reduction in light efficiency.

For example, embodiments of the present disclosure provide a display device architecture and fabrication method that collectively enhance image quality by addressing both lateral and vertical leakage current pathways. The integration of structural features—such as the spacer formed on the planarization layer and the disconnection of the light-emitting stack along the spacer—enables precise electrical isolation between adjacent sub-pixels. This isolation reduces color mixing and improves emission uniformity.

The aspects and effects of the present disclosure are not limited to the above-described aspects and effects and other aspects and effects which are not described herein will become apparent to those skilled in the art from the following description or from learning by practicing the present disclosure.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following description of example embodiments thereof with reference to the accompanied drawings, in which:

FIG. 1 is an exploded perspective view illustrating a display device according to one or more embodiments of the present disclosure;

FIG. 2 is a block diagram illustrating the display device according to one or more embodiments of the present disclosure;

FIG. 3 is an equivalent circuit diagram of a first sub-pixel according to one or more embodiments of the present disclosure;

FIG. 4 is a layout diagram illustrating an example of the display panel according to one or more embodiments of the present disclosure;

FIG. 5 is a layout diagram illustrating an example of a display area of FIG. 4 according to one or more embodiments of the present disclosure;

FIG. 6 is a cross-sectional view illustrating an example of the display panel taken along the line I1-I1’ of FIG. 5 according to one or more embodiments of the present disclosure;

FIG. 7 is an enlarged view of the area A1 of FIG. 6 according to one or more embodiments of the present disclosure;

FIG. 8 is an enlarged view of the area A2 of FIG. 7 according to one or more embodiments of the present disclosure;

FIG. 9 is a layout diagram illustrating an example of the display area of FIG. 4 according to one or more embodiments of the present disclosure;

FIG. 10 is a cross-sectional view illustrating an example of the display panel taken along the line I2-I2’ of FIG. 9 according to one or more embodiments of the present disclosure;

FIG. 11 is a layout diagram illustrating an example of the display area of FIG. 4 according to one or more embodiments of the present disclosure;

FIG. 12 is a schematic diagram of a second electrode of FIG. 11 according to one or more embodiments of the present disclosure;

FIG. 13 is an enlarged view of a portion of the display area of FIG. 11 according to one or more embodiments of the present disclosure;

FIGS. 14, 15, 16, 17, 18, 19, 20, and FIG. 21 are process cross-sectional views for describing a method for fabricating a display device according to one or more embodiments of the present disclosure;

FIG. 22 is a perspective view illustrating a head mounted display device according to one or more embodiments of the present disclosure;

FIG. 23 is an exploded perspective view illustrating an example of the head mounted display device of FIG. 22 according to one or more embodiments of the present disclosure;

FIG. 24 is a block diagram of an electronic device according to one or more embodiments of the present disclosure; and

FIGS. 25, 26, and FIG. 27 are schematic diagrams illustrating electronic devices according to various embodiments of the present disclosure.

### DETAILED DESCRIPTION

The present disclosure will now be described more fully hereinafter with reference to the accompanying drawings, in which example embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that if (e.g., when) a layer is referred to as being "on" another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers indicate the same or like components throughout the disclosure. In the accompanied drawings, the thickness of layers and regions may be exaggerated for clarity. In one or more embodiments, when an element is described to be “connected to” or “coupled to” another element, it may be construed as being “electrically connected to” or “electrically coupled to” the other element directly but also as possibly having another electrically conductive element arranged between the element and the other element. In one or more embodiments, when an element is described to be “disconnected” along a spacer, it may be constructed that the element is disconnected from an adjacent/neighboring like element, for example, located in a neighboring sub-pixel.

Although the terms "first", "second", and/or the like may be used herein to describe one or more suitable elements, these elements, should not be limited by these terms. These terms may be used to distinguish one element from another element. Thus, a first element discussed herein may be termed a second element without departing from teachings of one or more embodiments. The description of an element as a "first" element may not require or imply the presence of a second element or other elements. The terms "first", "second", and/or the like may also be used herein to differentiate different categories or sets of elements. For conciseness, the terms "first", "second", and/or the like may represent "first-category (or first-set)", "second-category (or second-set)", and/or the like, respectively.

Features of one or more suitable embodiments of the present disclosure may be combined partially or totally. As will be clearly appreciated by those skilled in the art, technically one or more suitable interactions and operations are possible. Various embodiments may be practiced individually or in combination.

Hereinafter, one or more embodiments of the present disclosure will be described with reference to the accompanying drawings.

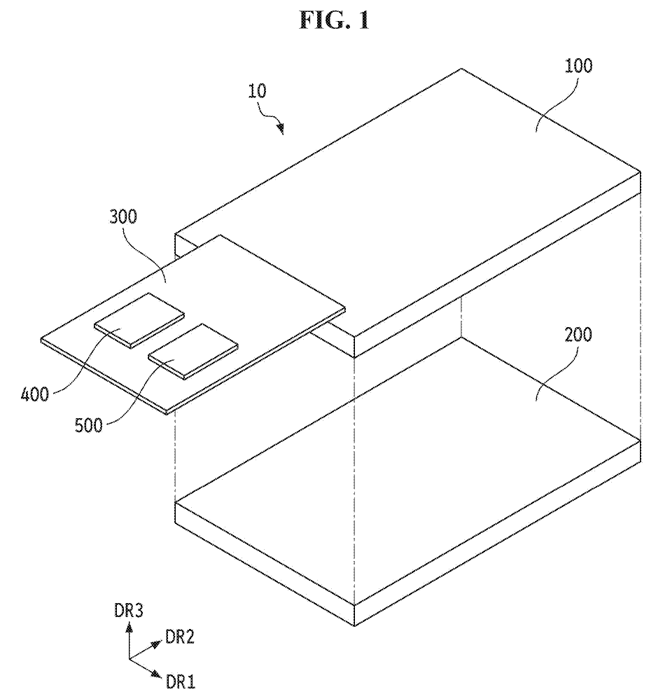

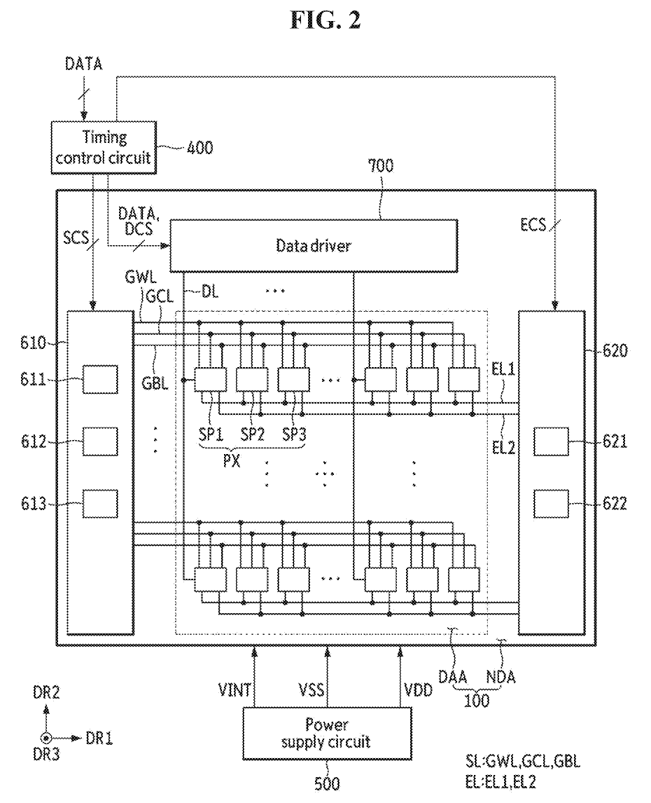

FIG. 1 is an exploded perspective view illustrating a display device according to one or more embodiments of the present disclosure. FIG. 2 is a block diagram illustrating the display device according to one or more embodiments of the present disclosure.

Referring to FIG. 1 and FIG. 2, a display device 10 according to one or more embodiments is a device displaying a moving image or a still image (e.g., displaying static and/or dynamic images). The display device 10 according to one or more embodiments may be applied to portable electronic devices such as a mobile phone, a smart phone, a tablet personal computer (PC), a mobile communication terminal, an electronic notebook, an electronic book, a portable multimedia player (PMP), navigation, and/or an ultra-mobile PC (UMPC). For example, the display device 10 according to one or more embodiments may be applied to a display unit of a television, a laptop computer, a monitor, a billboard, or an Internet of Things (IoT) device. In one or more embodiments, the display device 10 may be applied to a smart watch, a watch phone, and/or a head mounted display (HMD) for implementing virtual reality and augmented reality.

The display device 10 according to one or more embodiments may include a display panel 100, a heat dissipation layer 200, a circuit board 300, a timing control circuit 400, and a power supply circuit 500.

In one or more embodiments, the display panel 100 may be formed in a planar shape, for example, similar to a quadrangle. For example, the display panel 100 may have a planar shape, similar to a quadrangle, that has short sides in a first direction DR1 and long sides in a second direction DR2 intersecting the first direction DR1. In the display panel 100, a corner where the short side in the first direction DR1 and the long side in the second direction DR2 meet may be rounded to have a set or predetermined curvature or may be formed at a right angle. The planar shape of the display panel 100 is not limited to the quadrangle, and may be formed in a shape similar to other polygon(s), circle, or oval. A planar shape of the display device 10 may follow the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, a light emitting driver 620, and a data driver 700. The display panel 100 may be divided into a display area DAA displaying an image and a non-display area NDA that does not display an image, as illustrated in FIG. 2.

The plurality of pixels PX may be arranged in the display area DAA. The plurality of pixels PX may be arranged in a matrix form in the first direction DR1 and the second direction DR2. In one or more embodiments, the plurality of scan lines SL and the plurality of emission control lines EL may extend in the first direction DR1 and may be arranged in the second direction DR2. The plurality of data lines DL may extend in the second direction DR2 and may be arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

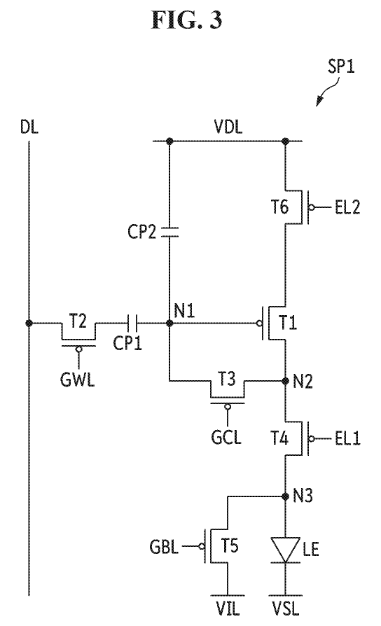

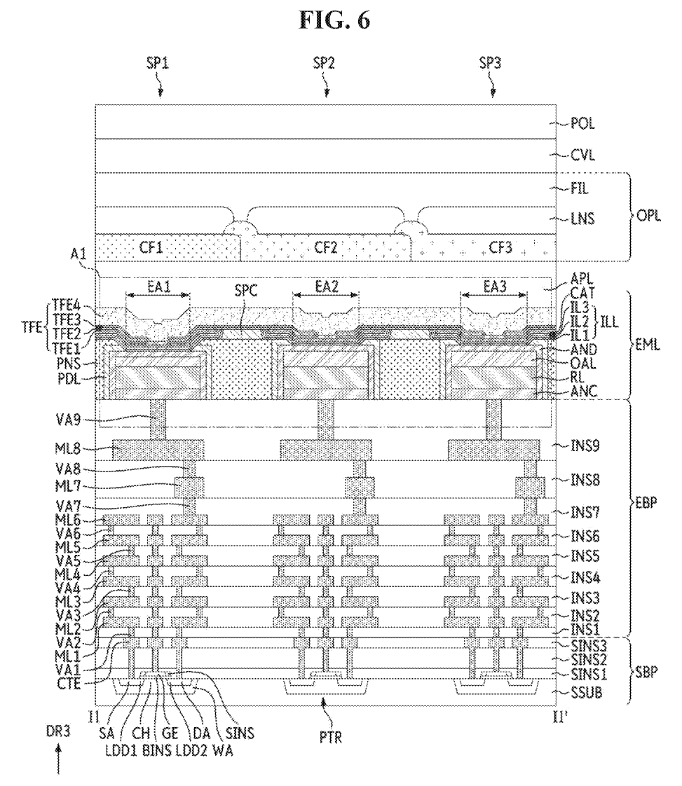

The plurality of pixels PX may include a plurality of sub-pixels SP1, SP2, and SP3. The plurality of sub-pixels SP1, SP2, and SP3 may each include a plurality of pixel transistors as illustrated in FIG. 3, and the plurality of pixel transistors may be formed through a semiconductor process and may be arranged on a semiconductor substrate (SSUB in FIG. 6). For example, in one or more embodiments, the plurality of pixel transistors of the data driver 700 may each be formed of a Complementary Metal Oxide Semiconductor (CMOS), but embodiments of the present disclosure are not limited thereto.

Each of the plurality of sub-pixels SP1, SP2, and SP3 may be connected to one (e.g., any one) write scan line GWL among the plurality of write scan lines GWL, one (e.g., any one) control scan line GCL among the plurality of control scan lines GCL, one (e.g., any one) bias scan line GBL among the plurality of bias scan lines GBL, one (e.g., any one) first emission control line EL1 among the plurality of first emission control lines EL1, one (e.g., any one) second emission control line EL2 among the plurality of second emission control lines EL2, and one (e.g., any one) data line DL among the plurality of data lines DL. Each of the plurality of sub-pixels SP1, SP2, and SP3 may receive a data voltage of the data line DL according to a write scan signal of the write scan line GWL, and may be to emit light from a light emitting element according to the data voltage.

In one or more embodiments, the scan driver 610, the light emitting driver 620, and the data driver 700 may be arranged in the non-display area NDA.

The scan driver 610 may include a plurality of scan transistors, and the light emitting driver 620 may include a plurality of light emitting transistors. The plurality of scan transistors and the plurality of light emitting transistors may be formed through a semiconductor process and may be formed on a semiconductor substrate (SSUB in FIG. 6). For example, in one or more embodiments, the plurality of scan transistors and the plurality of light emitting transistors may each be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed through a semiconductor process and may be formed on a semiconductor substrate (SSUB in FIG. 6). For example, in one or more embodiments, the plurality of data transistors may each be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this regard, the sub-pixels SP1, SP2, and SP3 may be selected by the write scan signals of the scan driver 610, and the data voltages (e.g., analog data voltages) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be arranged on one surface of the display panel 100, for example, a rear surface of the display panel 100. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

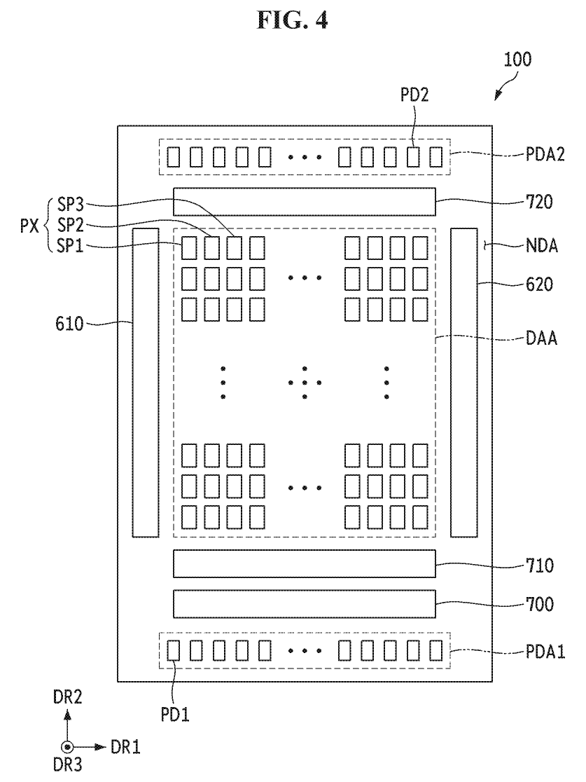

The circuit board 300 may be electrically connected to a plurality of first pads (PD1 in FIG. 4) of a first pad portion (PDA1 in FIG. 4) of the display panel 100 by using a conductive adhesive member such as an anisotropic conductive film. In one or more embodiments, the circuit board 300 may be a flexible printed circuit board or flexible film made of a flexible material. It is illustrated in FIG. 1 that the circuit board 300 is unfolded, but the circuit board 300 may be bent. In this regard, one end of the circuit board 300 may be arranged on the rear surface of the display panel 100 and/or a rear surface of the heat dissipation layer 200. The other end of the circuit board 300 may be connected to the plurality of first pads (PD1 in FIG. 4) of the first pad portion (PDA1 in FIG. 4) of the display panel 100 by using a conductive adhesive member. The one end of the circuit board 300 may be an end opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data DATA and the data timing control signal DCS to the data driver 700.

The power supply circuit 500 may generate a plurality of panel driving voltages according to a power voltage from the outside. For example, in one or more embodiments, the power supply circuit 500 may generate a first driving voltage VSS, a second driving voltage VDD, and a third driving voltage VINT and supply the generated driving voltages to the display panel 100. The first driving voltage VSS, the second driving voltage VDD, and the third driving voltage VINT will be described later with reference to FIG. 3.

Each of the timing control circuit 400 and the power supply circuit 500 may be formed as an integrated circuit (IC) and attached to a (e.g., one) surface of the circuit board 300. In this regard, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be arranged in the non-display area NDA of the display panel 100, similarly to the scan driver 610, the light emitting driver 620, and the data driver 700. In these embodiments, the timing control circuit 400 may include a plurality of timing transistors, and the power supply circuit 500 may include a plurality of power transistors. The plurality of timing transistors and the plurality of power transistors may be formed through a semiconductor process and may be formed on a semiconductor substrate (SSUB in FIG. 6). For example, in one or more embodiments, the plurality of timing transistors and the plurality of power transistors may be formed of CMOS, but embodiments of the present disclosure are not limited thereto. In one or more embodiments, each of the timing control circuit 400 and the power supply circuit 500 may be arranged between the data driver 700 and the first pad portion (PDA1 in FIG. 4).

FIG. 3 is an equivalent circuit diagram of a first sub-pixel according to one or more embodiments of the present disclosure.

Referring to FIG. 3, a first sub-pixel SP1 may be connected to a write scan line GWL, a control scan line GCL, a bias scan line GBL, a first emission control line EL1, a second emission control line EL2, and a data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In this regard, the first driving voltage VSS may be a voltage lower than the third driving voltage VINT. The second driving voltage VDD may be a voltage higher than the third driving voltage VINT.

The first sub-pixel SP1 may include a plurality of transistors T1 to T6, a light emitting element LE, a first capacitor CP1, and a second capacitor CP2.

The light emitting element LE emits light according to a driving current flowing through a channel of a first transistor T1. An amount (e.g., emission intensity) of light emitted from the light emitting element LE may be proportional to the driving current. The light emitting element LE may be arranged between a fourth transistor T4 and the first driving voltage line VSL. A first electrode of the light emitting element LE may be connected to a drain electrode of the fourth transistor T4, and a second electrode thereof may be connected to the first driving voltage line VSL. The first electrode of the light emitting element LE may be an anode electrode, and the second electrode of the light emitting element LE may be a cathode electrode. In one or more embodiments, the light emitting element LE may be an organic light emitting diode including a first electrode, a second electrode, and an organic light emitting layer arranged between the first electrode and the second electrode, but embodiments of the present disclosure are not limited thereto. For example, in one or more embodiments, the light emitting element LE may be an inorganic light emitting element including a first electrode, a second electrode, and an inorganic semiconductor arranged between the first electrode and the second electrode. In these embodiments, the light emitting element LE may be a micro light emitting diode.

The first transistor T1 may be a driving transistor that controls a source-drain current (hereinafter, referred to as “driving current”) flowing between a source electrode and a drain electrode according to a voltage applied to a gate electrode thereof. The first transistor T1 may include the gate electrode connected to a first node N1, the source electrode connected to a drain electrode of a sixth transistor T6, and the drain electrode connected to a second node N2.

A second transistor T2 may be arranged between one electrode of the first capacitor CP1 and the data line DL. The second transistor T2 is turned on by the write scan signal of the write scan line GWL and connects the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be arranged between the first node N1 and the second node N2. The third transistor T3 is turned on by a write control signal of the write control line GCL and connects the first node N1 to the second node N2. Accordingly, when the gate electrode and the source drain electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be arranged between the third node N3 and the third driving voltage line VIL. The fifth transistor T5 is turned on by the bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be arranged between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor CP1, and the one electrode of the second capacitor CP2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, in one or more embodiments, each of the first to sixth transistors T1 to T6 may be a P-type (kind) MOSFET, but embodiments of the present disclosure are not limited thereto. In one or more other embodiments, each of the first to sixth transistors T1 to T6 may be an N-type (kind) MOSFET. In one or more other embodiments, each of some of the first to sixth transistors T1 to T6 may be a P-type (kind) MOSFET, and each of the remaining transistors may be an N-type (kind) MOSFET.

It is illustrated in FIG. 3 that the first sub-pixel SP1 includes the six transistors T1 to T6 and the two capacitors CP1 and CP2, but it should be noted that the equivalent circuit diagram of the first sub-pixel SP1 is not limited to that illustrated in FIG. 3. For example, the number of transistors and the number of capacitors of the first sub-pixel SP1 are not limited to that illustrated in FIG. 3.

In addition, an equivalent circuit diagram of a second sub-pixel SP2 and an equivalent circuit diagram of a third sub-pixel SP3 may each be substantially the same as the equivalent circuit diagram of the first sub-pixel SP1 described with reference to FIG. 3. Therefore, the descriptions of the equivalent circuit diagram of the second sub-pixel SP2 and the equivalent circuit diagram of the third sub-pixel SP3 are not provided in the present disclosure.

FIG. 4 is a layout diagram illustrating an example of a display panel according to one or more embodiments of the present disclosure.

Referring to FIG. 4, the display area DAA of the display panel 100 according to one or more embodiments may include a plurality of pixels PX arranged in a matrix form. The non-display area NDA of the display panel 100 according to one or more embodiments may include a scan driver 610, a light emitting driver 620, a data driver 700, a first distribution circuit 710, a second distribution circuit 720, a first pad portion PDA1, and a second pad portion PDA2.

The scan driver 610 may be arranged on a first side of the display area DAA, and the light emitting driver 620 may be arranged on a second side (e.g., opposite the first side) of the display area DAA. For example, the scan driver 610 may be arranged on one side of the display area DAA in the first direction DR1, and the light emitting driver 620 may be arranged on the other side of the display area DAA in the first direction DR1. For example, the scan driver 610 may be arranged on a left side of the display area DAA, and the light emitting driver 620 may be arranged on a right side of the display area DAA, as shown in FIG. 4. However, embodiments of the present disclosure are not limited thereto, for example, in one or more embodiments, the scan driver 610 and the light emitting driver 620 may be arranged on both (e.g., simultaneously) the first side and the second side of the display area DAA.

The first pad portion PDA1 may include a plurality of first pads PD1 connected to pads or bumps of the circuit board 300 through a conductive adhesive member. The first pad portion PDA1 may be arranged on a third side of the display area DAA. For example, the first pad portion PDA1 may be arranged on one side of the display area DAA in the second direction DR2. The first pad portion PDA1 may be arranged on the outside of the data driver 700 in the second direction DR2. For example, the first pad portion PDA1 may be arranged closer to an edge of the display panel 100 than the data driver 700. In other words, the first pad portion PDA1 may be arranged such that it lies between the data driver 700 and the edge (outer boundary) of the display panel 100 in the second direction DR2.

The second pad portion PDA2 may include a plurality of second pads PD2 corresponding to test pads for testing whether the display panel 100 is normally operating. The plurality of second pads PD2 may be connected to a jig or probe pin or to a test circuit board during a test process. The test circuit board may be a printed circuit board made of a rigid material or a flexible printed circuit board made of a flexible material.

The second pad portion PDA2 may be arranged on a fourth side (opposite the third side) of the display area DAA. For example, the second pad portion PDA2 may be arranged on the other side of the display area DAA in the second direction DR2. The second pad portion PDA2 may be arranged on the outside of the second distribution circuit 720 in the second direction DR2. For example, the second pad portion PDA2 may be arranged closer to the edge of the display panel 100 than the second distribution circuit 720. In other words, the second pad portion PDA2 may be arranged such that it lies between the second distribution circuit 720 and the edge (outer boundary) of the display panel 100 in the second direction DR2.

The first distribution circuit 710 distributes the data voltages applied through the first pad portion PDA1 to the plurality of data lines DL. For example, in one or more embodiments, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be arranged on the third side of the display area DAA of the display panel 100. For example, the first distribution circuit 710 may be arranged on one side of the display area DAA in the second direction DR2. For example, the first distribution circuit 710 may be arranged on a lower side of the display area DAA.

The second distribution circuit 720 distributes signals applied through the second pad portion PDA2 to the scan driver 610, the light emitting driver 620, and the data lines DL. The second pad portion PDA2 and the second distribution circuit 720 may be components for testing the operation of each pixel PX of the display area DAA. The second distribution circuit 720 may be arranged on the fourth side of the display area DAA of the display panel 100. For example, the second distribution circuit 720 may be arranged on the other side of the display area DAA in the second direction DR2. For example, the second distribution circuit 720 may be arranged on an upper side of the display area DAA.

In the context of the present disclosure and unless defined otherwise, "one side of the display area DAA in the second direction DR2" refers to a specific side of the display area along the direction labeled as DR2. For instance, if DR2 represents a vertical direction, this may indicate the bottom side of the display area. Conversely, "the other side of the display area DAA in the second direction DR2" refers to the opposite side of the display area along the same direction DR2, which, continuing the previous example, may indicate the top side of the display area. These phrases are used to describe the positioning of components, such as distribution circuits, on opposite sides of the display area along the specified direction DR2.

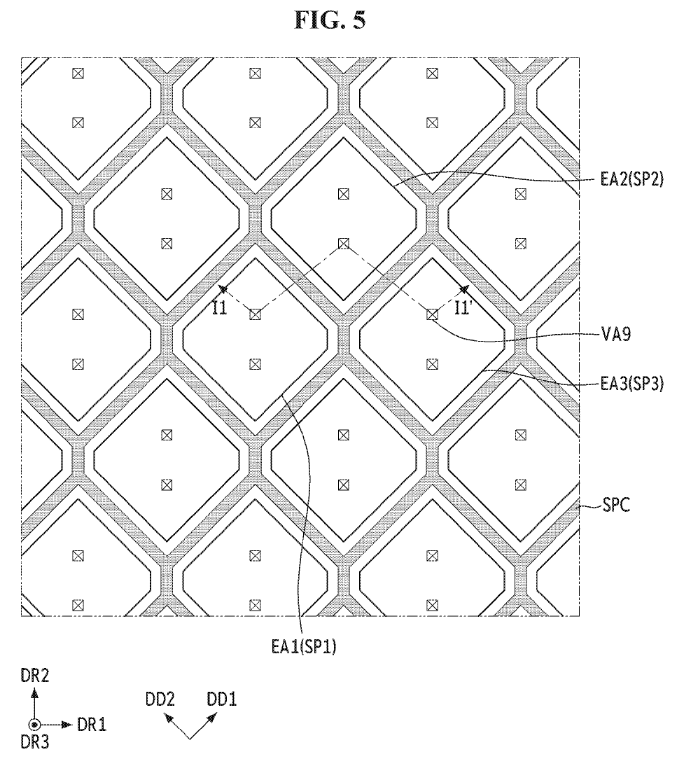

FIG. 5 is a layout diagram illustrating one example of the display area of FIG. 4 according to one or more embodiments of the present disclosure.

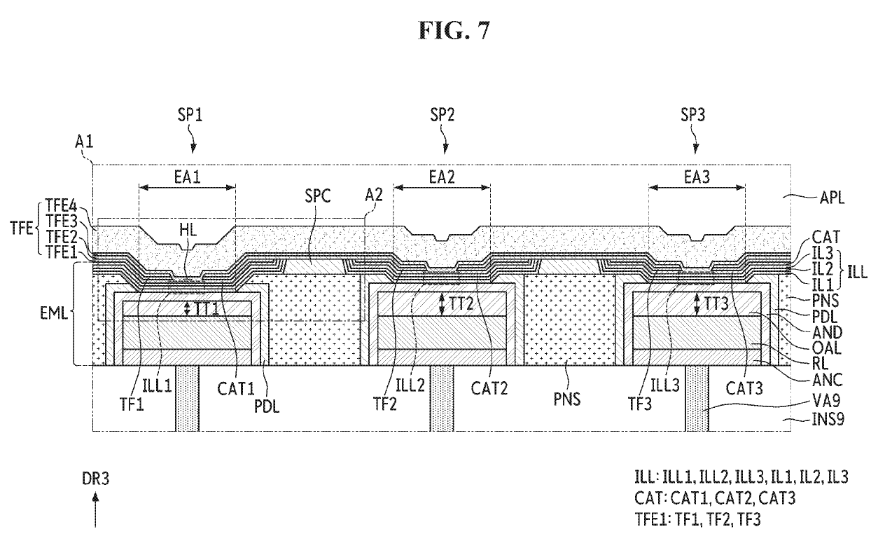

Referring to FIG. 5, each of the plurality of pixels PX may include a first light emitting area EA1, which is a light emitting area of the first sub-pixel SP1, a second light emitting area EA2, which is a light emitting area of the second sub-pixel SP2, and a third light emitting area EA, which is a light emitting area of the third sub-pixel SP3. The first emission area EA1, the second emission area EA2, and the third emission area EA3 may be separated by a spacer SPC, and each of the first emission area EA1, the second emission area EA2, and the third emission area EA3 may include a via VA9. The detailed descriptions of the spacer SPC and the via VA9 will be described in more detail later with reference to FIG. 6 and FIG. 7.

Each of the first light emitting area EA1, the second light emitting area EA2, and the third light emitting area EA3 may have a polygonal shape, a circular shape, an elliptical shape, or an irregular planar shape. For example, in one or more embodiments, the first light emitting area EA1, the second light emitting area EA2, and the third light emitting area EA3 may each have a hexagonal planar shape including six straight lines/edges, but embodiments of the present disclosure are not limited thereto.

An area of the first light emitting area EA1, an area of the second light emitting area EA2, and an area of the third light emitting area EA3 may be the same or different from each other.

In one or more embodiments, the first light emitting area EA1 and the second light emitting area EA2 may be adjacent to each other in a first diagonal direction DD1, the second light emitting area EA2 and the third light emitting area EA3 may be adjacent to each other in a second diagonal direction DD2, and the first light emitting area EA1 and the third light emitting area EA3 may be adjacent to each other in the first direction DR1. The first diagonal direction DD1, which is a direction between the first direction DR1 and the second direction DR2, may indicate a direction inclined by 45 degrees with respect to the first direction DR1 and the second direction DR2, and the second diagonal direction DD2 may be a direction perpendicular/orthogonal to the first diagonal direction DD1.

The first sub-pixel SP1 may be to emit first light that has passed through a first color filter (CF1 in FIG. 6) among light emitted from the first light emitting area EA1, the second sub-pixel SP2 may be to emit second light that has passed through a second color filter (CF2 in FIG. 6) among light emitted from the second light emitting area EA2, and the third sub-pixel SP3 may be to emit third light that has passed through a third color filter (CF3 in FIG. 6) among light emitted from the third light emitting area EA3. Here, the first light may be light of a green wavelength band, the second light may be light of a blue wavelength band, and the third light may be light of a red wavelength band. For example, the red wavelength band may indicate that a main peak wavelength of light is included in a wavelength band of approximately about 600 nm to about 750 nm, the green wavelength band may indicate that a main peak wavelength of light is included in a wavelength band of approximately about 480 nm to about 560 nm, and the blue wavelength band may indicate that a main peak wavelength of light is included in a wavelength band of approximately about 370 nm to about 460 nm.

It is illustrated in FIG. 5 that each of the plurality of pixels PX includes the three light emitting areas EA1, EA2, and EA3, but embodiments of the present specification are not limited thereto. For example, in one or more embodiments, each of the plurality of pixels PX may include four light emitting areas.

As illustrated in FIG. 5, the spacer SPC may surround each of the light emitting areas EA1, EA2, and EA3. For example, in plan view, the spacer SPC may have a closed curve mesh shape around (e.g., surrounding) each of the first light emitting area EA1, the second light emitting area EA2, and the third light emitting area EA3.

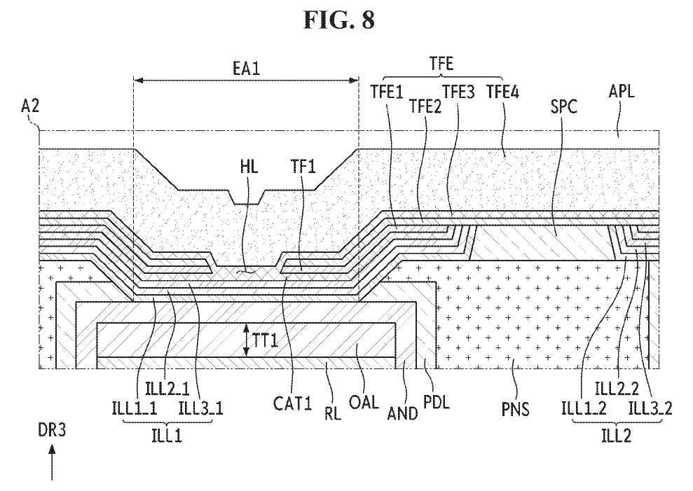

FIG. 6 is a cross-sectional view illustrating an example of the display panel taken along the line I1-I1’ of FIG. 5 according to one or more embodiments of the present disclosure, FIG. 7 is an enlarged view of the area A1 of FIG. 6 according to one or more embodiments, and FIG. 8 is an enlarged view of the area A2 of FIG. 7 according to one or more embodiments.

Referring to FIG. 6 and FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may include (e.g., be) the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type (kind) impurities. A plurality of well areas WA may be arranged in an upper surface of the semiconductor substrate SSUB. The plurality of well areas WA may each be an area doped with second-type (kind) impurities. The second-type (kind) impurity may be different from the first-type (kind) impurity described above. For example, in one or more embodiments, if (e.g., when) the first-type (kind) impurity is a p-type (kind) impurity, the second-type (kind) impurity may be an n-type (kind) impurity. In one or more embodiments, if (e.g., when) the first-type (kind) impurity is an n-type (kind) impurity, the second-type (kind) impurity may be a p-type (kind) impurity.

Each of the plurality of well areas WA may include a source area SA corresponding to a source electrode of a pixel transistor PTR, a drain area DA corresponding to a drain electrode thereof, and a channel area CH arranged between the source area SA and the drain area DA.

A lower insulating layer BINS may be arranged between a gate electrode GE and each well area WA. A side insulating layer SINS may be arranged on a side surface of the gate electrode GE. The side insulating layer SINS may be arranged on the lower insulating layer BINS.

Each of the source area SA and the drain area DA may be an area doped with the first-type (kind) impurities. The gate electrode GE of each pixel transistor PTR may overlap a respective well area WA in the third direction DR3, which is a thickness direction of the semiconductor substrate SSUB. The channel area CH may overlap the respective gate electrode GE in the third direction DR3. The source area SA may be arranged on one side of the gate electrode GE, and the drain area DA may be arranged on the other side of the gate electrode GE.

Each of the plurality of well areas WA may further include a first low-concentration impurity area LDD1 arranged between the channel area CH and the source area SA and a second low-concentration impurity area LDD2 arranged between the channel area CH and the drain area DA. The first low-concentration impurity area LDD1 may be an area having an impurity concentration lower than that of the source area SA due to the lower insulating layer BINS. The second low-concentration impurity area LDD2 may be an area having an impurity concentration lower than that of the drain area DA due to the lower insulating layer BINS. A distance between the source area SA and the drain area DA may be increased due to the first low-concentration impurity area LDD1 and the second low-concentration impurity area LDD2. Because a length of the channel area CH of each of the pixel transistors PTR may increase, punch-through and hot carrier phenomena caused by a short channel may be prevented or reduced.

A first semiconductor insulating layer SINS1 may be arranged on the semiconductor substrate SSUB. The first semiconductor insulating layer SINS1 may include a silicon nitride carbon (SiCN) film or a silicon oxide (SiOₓ)-based inorganic film, but embodiments of the present disclosure are not limited thereto.

A second semiconductor insulating layer SINS2 may be arranged on the first semiconductor insulating layer SINS1. The second semiconductor insulating layer SINS2 may include a silicon oxide (SiOₓ)-based inorganic film, but embodiments of the present disclosure are not limited thereto.

The plurality of contact terminals CTE may be arranged on the second semiconductor insulating layer SINS2. Each of the plurality of contact terminals CTE may be connected to corresponding one of the gate electrode GE, the source area SA, and the drain area DA of each of the pixel transistors PTR through a hole penetrating through the first semiconductor insulating layer SINS1 and the second semiconductor insulating layer SINS2. The plurality of contact terminals CTE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof.

A third semiconductor insulating layer SINS3 may be arranged on a side surface of each of the plurality of contact terminals CTE. An upper surface of each of the plurality of contact terminals CTE may be exposed without being covered by the third semiconductor insulating layer SINS3. The third semiconductor insulating layer SINS3 may include a silicon oxide (SiOₓ)-based inorganic film, but embodiments of the present disclosure are not limited thereto.

In one or more embodiments, the semiconductor substrate SSUB may be replaced with a glass substrate or a polymer resin substrate such as polyimide. In these embodiments, thin film transistors may be arranged on the glass substrate or the polymer resin substrate. The glass substrate may be a rigid substrate that is not bent, and the polymer resin substrate may be a flexible substrate that may be bent or curved.

The light emitting element backplane EBP may include a plurality of conductive layers ML1 to ML8, a plurality of via layers VA1 to VA9, and a plurality of insulating layers INS1 to INS9. In addition, the light emitting element backplane EBP may include a plurality of insulating layers INS1 to INS9 respectively arranged between the first to eighth conductive layers ML1 to ML8.

The first to eighth conductive layers ML1 to ML8 serve to implement the circuit of the first sub-pixel SP1 illustrated in FIG. 3 by connecting the plurality of contact terminals CTE exposed from the semiconductor backplane SBP. For example, in one or more embodiments, the first to sixth transistors T1 to T6 are simply formed in the semiconductor backplane SBP, but the first to sixth transistors T1 to T6 and the first and second capacitors CP1 and CP2 are connected through the first to eighth conductive layers ML1 to ML8. In addition, the connection between a drain area corresponding to the drain electrode of the fourth transistor T4, a source area corresponding to the source electrode of the fifth transistor T5, and a first electrode AND of the light emitting element LE is also achieved through the first to eighth conductive layers ML1 to ML8.

A first insulating layer INS1 may be arranged on the semiconductor backplane SBP. Each first via layer VA1 may penetrate through the first insulating layer INS1 and be connected to the contact terminal CTE exposed from the semiconductor backplane SBP. Each first conductive layer ML1 may be arranged on the first insulating layer INS1 and may be connected to a corresponding first via layer VA1.

A second insulating layer INS2 may be arranged on the first insulating layer INS1 and the first conductive layers ML1. Each second via layer VA2 may be connected to a corresponding first conductive layer ML1 exposed by penetrating through the second insulating layer INS2. Each second conductive layer ML2 may be arranged on the second insulating layer INS2 and may be connected to a corresponding second via layer VA2.

A third insulating layer INS3 may be arranged on the second insulating layer INS2 and the second conductive layers ML2. Each third via layer VA3 may be connected to a corresponding second conductive layer ML2 exposed by penetrating through the third insulating layer INS3. Each third conductive layer ML3 may be arranged on the third insulating layer INS3 and may be connected to a corresponding third via layer VA3.

A fourth insulating layer INS4 may be arranged on the third insulating layer INS3 and the third conductive layers ML3. Each fourth via layer VA4 may be connected to a corresponding third conductive layer ML3 exposed by penetrating through the fourth insulating layer INS4. Each fourth conductive layer ML4 may be arranged on the fourth insulating layer INS4 and may be connected to a corresponding fourth via layer VA4.

A fifth insulating layer INS5 may be arranged on the fourth insulating layer INS4 and the fourth conductive layers ML4. Each fifth via layer VA5 may be connected to a corresponding fourth conductive layer ML4 exposed by penetrating through the fifth insulating layer INS5. Each fifth conductive layer ML5 may be arranged on the fifth insulating layer INS5 and may be connected to a corresponding fifth via layer VA5.

A sixth insulating layer INS6 may be arranged on the fifth insulating layer INS5 and the fifth conductive layers ML5. Each sixth via layer VA6 may be connected to a corresponding fifth conductive layer ML5 exposed by penetrating through the sixth insulating layer INS6. Each sixth conductive layer ML6 may be arranged on the sixth insulating layer INS6 and may be connected to a corresponding sixth via layer VA6.

A seventh insulating layer INS7 may be arranged on the sixth insulating layer INS6 and the sixth conductive layers ML6. Each seventh via layer VA7 may be connected to a corresponding sixth conductive layer ML6 exposed by penetrating through the seventh insulating layer INS7. Each seventh conductive layer ML7 may be arranged on the seventh insulating layer INS7 and may be connected to a corresponding seventh via layer VA7.

An eighth insulating layer INS8 may be arranged on the seventh insulating layer INS7 and the seventh conductive layers ML7. Each eighth via layer VA8 may be connected to a corresponding seventh conductive layer ML7 exposed by penetrating through the eighth insulating layer INS8. Each eighth conductive layer ML8 may be arranged on the eighth insulating layer INS8 and may be connected to a corresponding eighth via layer VA8.

The first to eighth conductive layers ML1 to ML8 and the first to eighth via layers VA1 to VA8 may include substantially a same material. In one or more embodiments, the first to eighth conductive layers ML1 to ML8 and the first to eighth via layers VA1 to VA8 may each include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. The first to eighth via layers VA1 to VA8 may include substantially the same material. The first to eighth insulating layers INS1 to INS8 may each include a silicon oxide (SiOₓ)-based inorganic film, but embodiments of the present disclosure are not limited thereto.

A thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than a thickness of the first via layer VA1, a thickness of the second via layer VA2, a thickness of the third via layer VA3, a thickness of the fourth via layer VA4, a thickness of the fifth via layer VA5, and a thickness of the sixth via layer VA6, respectively. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, in one or more embodiments, the thickness of the first conductive layer ML1 may be approximately 1,360 angstroms (Å) (i.e., 10⁻¹⁰ m), each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1,440 Å, and each of the thickness of the first via layer VA1, the thickness of the second via layer VA2, the thickness of the third via layer VA3, the thickness of the fourth via layer VA4, the thickness of the fifth via layer VA5, and the thickness of the sixth via layer VA6 may be approximately 1,150 Å.

A thickness of the seventh conductive layer ML7 and a thickness of the eighth conductive layer ML8 may each be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may each be greater than each of a thickness of the seventh via layer VA7 and a thickness of the eighth via layer VA8. The thickness of the seventh via layer VA7 and the thickness of the eighth via layer VA8 may each be greater than each of the thickness of the first via layer VA1, the thickness of the second via layer VA2, the thickness of the third via layer VA3, the thickness of the fourth via layer VA4, the thickness of the fifth via layer VA5, and the thickness of the sixth via layer VA6. The thickness of the seventh conductive layer ML7 and the thickness of the eighth conductive layer ML8 may be substantially the same. For example, in one or more embodiments, the thickness of the seventh conductive layer ML7 and the thickness of the eighth conductive layer ML8 may each be approximately 9,000 Å. The thicknesses of the seventh via layer VA7 and the eighth via layer VA8 may each be approximately (about) 6,000 Å.

A ninth insulating layer INS9 may be arranged on the eighth insulating layer INS8 and the eighth conductive layers ML8. The ninth insulating layer INS9 may include a silicon oxide (SiOₓ)-based inorganic film, but embodiments of the present disclosure are not limited thereto.

Each ninth via layer VA9 may be connected to a corresponding eighth conductive layer ML8 exposed by penetrating through the ninth insulating layer INS9. The ninth via layers VA9 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. In one or more embodiments, a thickness of the ninth via layer VA9 may be approximately 16,500 Å.

The display element layer EML may be arranged on the light emitting element backplane EBP. The display element layer EML may include a plurality of connection electrodes ANC, a plurality of reflective electrodes RL, a plurality of optical auxiliary layers OAL, a planarization layer PNS, a pixel defining layer PDL, a plurality of first electrodes AND, a light emitting stack ILL, and a second electrode CAT.

In addition, the display element layer EML may include a first light emitting area EA1, a second light emitting area EA2, and a third light emitting area EA3. Each of the first light emitting area EA1, the second light emitting area EA2, and the third light emitting area EA3 may be an area in which the first electrode AND, the light emitting stack ILL, and the second electrode CAT are sequentially stacked (e.g., in the stated order). Each of the first light emitting area EA1, the second light emitting area EA2, and the third light emitting area EA3 may be an area in which a light emitting element LE including the first electrode AND, the light emitting stack ILL, and the second electrode CAT is arranged. Each of the first light emitting area EA1, the second light emitting area EA2, and the third light emitting area EA3 may be partitioned by the pixel defining layer PDL.

The plurality of connection electrodes ANC may be arranged on the ninth insulating layer INS9. For example, the plurality of connection electrodes ANC may be arranged on the ninth insulating layer INS9 so as to overlap the plurality of ninth via layers VA9, respectively. In one or more embodiments, the plurality of connection electrodes ANC may include titanium nitride (TiN) or transparent conductive oxide. For example, the transparent conductive oxide may be Indium Tin Oxide (ITO) or Indium Zinc Oxide (IZO), but embodiments of the present disclosure are not limited thereto.

The connection electrode ANC of the first sub-pixel SP1, the connection electrode ANC of the second sub-pixel SP2, and the connection electrode ANC of the third sub-pixel SP3 may have a same thickness. Here, the thickness may be a size in the third direction DR3.

In each of the first sub-pixels SP1, the reflective electrode RL may be arranged on the connection electrode ANC. For example, in each of the first sub-pixels SP1, the reflective electrode RL may cover an upper surface of the connection electrode ANC.

In each of the second sub-pixels SP2, the reflective electrode RL may be arranged on the connection electrode ANC. For example, in each of the first sub-pixels SP1, the reflective electrode RL may cover an upper surface of the connection electrode ANC.

In each of the third sub-pixels SP3, the reflective electrode RL may be arranged on the connection electrode ANC. For example, in each of the third sub-pixels SP3, the reflective electrode RL may cover an upper surface of the connection electrode ANC.

The reflective electrode RL of the first sub-pixel SP1, the reflective electrode RL of the second sub-pixel SP2, and the reflective electrode RL of the third sub-pixel SP3 may have a same thickness. Here, the thickness may be a size in the third direction DR3.

Each reflective electrode RL may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. For example, in one or more embodiments, each reflective electrode RL may include aluminum (Al) having high reflectivity.

The optical auxiliary layers OAL may be respectively arranged on the reflective electrodes RL. An optical auxiliary layer OAL corresponding to one of the reflective electrodes RL may be arranged on the corresponding reflective electrodes RL. In one or more embodiments, the optical auxiliary layer OAL may include a silicon oxide (SiOₓ)-based inorganic film, but embodiments of the present disclosure are not limited thereto.

A thickness TT1 of the optical auxiliary layer OAL in the first sub-pixel SP1, a thickness TT2 of the optical auxiliary layer OAL in the second sub-pixel SP2, and a thickness TT3 of the optical auxiliary layer OAL in the third sub-pixel SP3 may be different. For example, in one or more embodiments, the thickness TT1 of the optical auxiliary layer OAL in the first sub-pixel SP1 may be the smallest. In addition, the thickness TT2 of the optical auxiliary layer OAL in the second sub-pixel SP2 may be greater than the thickness TT1 of the optical auxiliary layer OAL in the first sub-pixel SP1. The thickness TT3 of the optical auxiliary layer OAL in the third sub-pixel SP3 may be substantially the same as the thickness TT2 of the optical auxiliary layer OAL in the second sub-pixel SP2.

The thickness TT1 of the optical auxiliary layer OAL in the first sub-pixel SP1, the thickness TT2 of the optical auxiliary layer OAL in the second sub-pixel SP2, and the thickness TT3 of the optical auxiliary layer OAL in the third sub-pixel SP3 may be set by considering a main peak wavelength of first light, a main peak wavelength of second light, a main peak wavelength of third light, a distance from a first stack layer IL1 to the reflective electrode RL in the first light emitting area EA1, and a distance from a second stack layer IL2 to the reflective electrode RL in the second light emitting area EA2, and accordingly, a resonance distance of the first light, a resonance distance of the second light, and a resonance distance of the third light may be set.

Each light emitting element LE may include a first electrode AND, a light emitting stack ILL, and a second electrode CAT.

The first electrode AND of each of the light emitting elements LE may be arranged on a side surface of the connection electrode ANC, a side surface of the reflective electrode RL, an upper surface of the optical auxiliary layer OAL, and a side surface of the optical auxiliary layer OAL. For example, the first electrode AND of each of the light emitting elements LE may surround the optical auxiliary layer OAL, the reflective electrode RL, and the connection electrode ANC together with the ninth insulating layer INS9. As the first electrode AND of each of the light emitting elements LE is electrically connected to the reflective electrode RL and the connection electrode ANC by being in contact with the side surface of the reflective electrode RL and the side surface of the connection electrode ANC, a mask process may be reduced compared to if (e.g., when) the first electrode AND of each of the light emitting elements LE is connected to the reflective electrode RL exposed through a through hole penetrating through the optical auxiliary layer OAL, thereby reducing fabricating costs and increasing manufacturing efficiency. In addition, as the first electrode AND of each of the light emitting elements LE is electrically connected to the reflective electrode RL and the connection electrode ANC by being in contact with the side surface of the reflective electrode RL and the side surface of the connection electrode ANC, a light emitting area may be increased compared to if (e.g., when) the first electrode AND of each of the light emitting elements LE is connected to the reflective electrode RL exposed through a through hole penetrating through the optical auxiliary layer OAL.

The first electrode AND of each of the light emitting elements LE may be connected to the drain area DA or the source area SA of a corresponding pixel transistor PTR through the connection electrode ANC, the first to ninth via layers VA1 to VA9, the first to eighth conductive layers ML1 to ML8, and the contact terminal CTE.

The first electrode AND of each of the light emitting elements LE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or an alloy or a compound including any one thereof. For example, in one or more embodiments, the first electrode AND of each of the light emitting elements LE may include titanium nitride (TiN).

A thickness of the first electrode AND arranged on the upper surface of the optical auxiliary layer OAL may be smaller than a thickness of the first electrode AND arranged on the side surface of the connection electrode ANC, the side surface of the reflective electrode RL, and the side surface of the optical auxiliary layer OAL. For example, as the thickness of the first electrode AND arranged on the upper surface of the optical auxiliary layer OAL is formed to be approximately 50 Å or less, a light transmittance of the first electrode AND arranged on the upper surface of the optical auxiliary layer OAL may be improved. In addition, because the thickness of the first electrode AND arranged on the side surface of the connection electrode ANC, the side surface of the reflective electrode RL, and the side surface of the optical auxiliary layer OAL may be formed to be approximately 100 Å to 200 Å, an increase in contact resistance that may occur if (e.g., when) the first electrode AND is in contact with only the side surface of the connection electrode ANC and the side surface of the reflective electrode RL may be minimized or reduced.

The pixel defining layer PDL may be arranged on the ninth insulating layer INS9 to surround a side surface of the first electrode AND of each of the light emitting elements LE and the edge of an upper surface of the first electrode AND of each of the light emitting elements LE. For example, in plan view, the pixel defining layer PDL may be arranged on the ninth insulating layer INS9 to surround the first electrode AND of each of the light emitting elements LE. The pixel defining layer PDL may partition the first light emitting areas EA1, the second light emitting areas EA2, and the third light emitting areas EA3. In one or more embodiments, the pixel defining layer PDL may be made of a material including silicon nitride (SiNₓ).

The first light emitting area EA1 may be defined as an area in which the first electrode AND, the light emitting stack ILL, and the second electrode CAT are sequentially stacked in the first sub-pixel SP1 to emit light. The second light emitting area EA2 may be defined as an area in which the first electrode AND, the light emitting stack ILL, and the second electrode CAT are sequentially stacked in the second sub-pixel SP2 to emit light. The third light emitting area EA3 may be defined as an area in which the first electrode AND, the light emitting stack ILL, and the second electrode CAT are sequentially stacked in the third sub-pixel SP3 to emit light.

The planarization layer PNS may remove or flatten (e.g., planarizes) steps between the sub-pixels SP1, SP2, and SP3 caused by a difference in thickness of the optical auxiliary layer OAL between the sub-pixels SP1, SP2, and SP3. The planarization layer PNS may be arranged on the ninth insulating layer INS9. For example, the planarization layer PNS may be arranged between the first electrodes AND adjacent to each other on the ninth insulating layer INS9. In this regard, the pixel defining layer PDL described above may be arranged between the planarization layer PNS and the first electrode AND. For example, a portion of the planarization layer PNS may be arranged on the pixel defining layer PDL so as to overlap the edge of the upper surface of each first electrode AND.

The planarization layer PNS may be arranged between the connection electrodes ANC adjacent to each other in the first direction DR1 or the second direction DR2. The planarization layer PNS may be arranged between the reflective electrodes RL adjacent to each other in the first direction DR1 or the second direction DR2. The planarization layer PNS may be arranged between the optical auxiliary layers OAL adjacent to each other in the first direction DR1 or the second direction DR2.

As illustrated in FIGS. 6, 7, and FIG. 8, the spacer SPC may be arranged on the planarization layer PNS. For example, the spacer SPC may be arranged on the planarization layer PNS so as not to overlap the pixel defining layer PDL. The spacer SPC may protrude toward the encapsulation layer TFE on (e.g., from) the planarization layer PNS. For example, the spacer SPC may protrude along the third direction DR3 on (e.g., from) the planarization layer PNS. In plan view, the spacer SPC may surround each of the first light emitting area EA1, the second light emitting area EA2, and the third light emitting area EA3 (see FIG. 5). In addition, in plan view, the spacer SPC may surround each first electrode AND. In addition, in plan view, the spacer SPC may surround the pixel defining layer PDL. The spacer SPC may serve as a separator that disconnects the light emitting stack ILL, the second electrode CAT, and a first encapsulation layer TFE1 for each sub-pixel, which will be described later. The spacers SPC may include a same material as the pixel defining layer PDL. For example, in one or more embodiments, the spacer SPC may be made of a material including silicon nitride (SiNₓ).

The light emitting stack ILL may include a plurality of stack layers IL1, IL2, and IL3. It is illustrated in FIG. 7 that the light emitting stack ILL has a three-tandem structure including a first stack layer IL1, a second stack layer IL2, and a third stack layer IL3, but embodiments of present disclosure are not limited thereto. For example, in one or more embodiments, the light emitting stack ILL may have a two-tandem structure including two stack layers.

In the three-tandem structure, the light emitting stack ILL may have a tandem structure including a plurality of stack layers IL1, IL2, and IL3 that emit different lights. For example, in one or more embodiments, the light emitting stack ILL may include a first stack layer IL1, a second stack layer IL2, and a third stack layer IL3. The first stack layer IL1, the second stack layer IL2, and the third stack layer IL3 may be sequentially stacked (e.g., in the stated order). Here, the first stack layer IL1, the second stack layer IL2, and the third stack layer IL3 may provide light of different colors.

The first stack layer IL1 may be arranged on the first electrodes AND and the planarization layer PNS. The first stack layer IL1 may be connected to the first electrode AND of the first sub-pixel SP1 in the first light emitting area EA1, to the first electrode AND of the second sub-pixel SP2 in the second light emitting area EA2, and to the first electrode AND of the third sub-pixel SP3 in the third light emitting area EA3. The first stack layer IL1 may have a structure in which a first hole transporting layer, a first organic light emitting layer, and a first electron transporting layer are sequentially stacked (e.g., in the stated order). The second stack layer IL2 may have a structure in which a second hole transporting layer, a second organic light emitting layer, and a second electron transporting layer are sequentially stacked (e.g., in the stated order). The third stack layer IL3 may have a structure in which a third hole transporting layer, a third organic light emitting layer, and a third electron transporting layer are sequentially stacked (e.g., in the stated order). Here, the first organic light emitting layer, the second organic light emitting layer, and the third organic light emitting layer may provide light of different colors.

The second stack layer IL2 may be arranged on the first stack layer IL1. For example, the second stack layer may be arranged between the first stack layer IL1 and the third stack layer IL3.

The third stack layer IL3 may be arranged on the second stack layer IL2. For example, the third stack layer IL3 may be arranged between the second stack layer IL2 and the second electrode CAT.

The light emitting stack ILL may further include at least one charge generation layer. For example, in one or more embodiments, the light emitting stack ILL may further include a first charge generation layer and a second charge generation layer.

The first charge generation layer may be arranged between the first stack layer IL1 and the second stack layer IL2. The first charge generation layer may supply charges (e.g., holes) to the second stack layer IL2 and electrons to the first stack layer IL1. The first charge generation layer may include an N-type (kind) charge generation layer that supplies electrons to the first stack layer IL1 and a P-type (kind) charge generation layer that supplies holes to the second stack layer IL2. The N-type (kind) charge generation layer may include a dopant of a metallic material.

The second charge generation layer may be arranged between the second stack layer IL2 and the third stack layer IL3. The second charge generation layer may supply charges (holes) to the third stack layer IL3 and electrons to the second stack layer IL2. The second charge generation layer may include an N-type (kind) charge generation layer that supplies electrons to the second stack layer IL2 and a P-type (kind) charge generation layer that supplies holes to the third stack layer IL3.

The light emitting stack ILL may be disconnected (or cut) on (or by) the spacer SPC to be separated for each sub-pixel. For example, the light emitting stack ILL may be disconnected (or cut) along the spacer SPC to be separated for each sub-pixel. For example, in one or more embodiments, the light emitting stack ILL may include a first divided light emitting stack ILL1 overlapping the first light emitting area EA1 of the first sub-pixel SP1, a second divided light emitting stack ILL2 overlapping the second light emitting area EA2 of the second sub-pixel SP2, and a third divided light emitting stack ILL3 overlapping the third light emitting area EA3 of the third sub-pixel SP3. Here, the first divided light emitting stack ILL1 of the first sub-pixel SP1, the second divided light emitting stack ILL2 of the second sub-pixel SP2, and the third divided light emitting stack ILL3 of the third sub-pixel SP3 may be separated on (or by) the spacer SPC so as not to be connected to each other. The first divided light emitting stack ILL1, the second divided light emitting stack ILL2, and the third divided light emitting stack ILL3 may each be arranged on a side surface of the spacer SPC. The first divided light emitting stack ILL1, the second divided light emitting stack ILL2, and the third divided light emitting stack ILL3 are not arranged on an upper surface of the spacer SPC. For example, the first divided light emitting stack ILL1, the second divided light emitting stack ILL2, and the third divided light emitting stack ILL3 do not overlap the upper surface of the spacer SPC.

As the light emitting stack ILL is divided into the first divided light emitting stack ILL1, the second divided light emitting stack ILL2, and the third divided light emitting stack ILL3 separated from each other for each sub-pixel, the stack layers IL1, IL2, and IL3 of each light emitting stack ILL may also be respectively separated from each other for each sub-pixel. For example, the stack layers IL1, IL2, and IL3 of each light emitting stack ILL may also be disconnected (or cut) along the spacer SPC to be separated for each sub-pixel. For example, the first stack layer IL1 of the first divided light emitting stack ILL1, the first stack layer IL1 of the second divided light emitting stack ILL2, and the first stack layer IL1 of the third divided light emitting stack ILL3 may be separated on the spacer SPC so as not to be connected to each other. In addition, the second stack layer IL2 of the first divided light emitting stack ILL1, the second stack layer IL2 of the second divided light emitting stack ILL2, and the second stack layer IL2 of the third divided light emitting stack ILL3 may be separated on the spacer SPC so as not to be connected to each other. In addition, the third stack layer IL3 of the first divided light emitting stack ILL1, the third stack layer IL3 of the second divided light emitting stack ILL2, and the third stack layer IL3 of the third divided light emitting stack ILL3 may be separated on the spacer SPC so as not to be connected to each other. For example, as illustrated in FIG. 8, a first stack layer (e.g., a first divided stack layer ILL1_1) of the first divided light emitting stack ILL1 and a first stack layer (e.g., a first divided stack layer ILL1_2) of the second divided light emitting stack ILL2 may be separated from each other by the spacer SPC, a second stack layer (e.g., a second divided stack layer ILL2_1) of the first divided light emitting stack ILL1 and a second stack layer (e.g., a second divided stack layer ILL2_2) of the second divided light emitting stack ILL2 may be separated from each other by the spacer SPC, and a third stack layer (e.g., a third divided stack layer ILL3_1) of the first divided light emitting stack ILL1 and a third stack layer (e.g., a third divided stack layer ILL3_2) of the second divided light emitting stack ILL2 may be separated from each other by the spacer SPC. In this way, the third divided light emitting stack ILL3 may also include a first divided stack layer, a second divided stack layer, and a third divided stack layer that are separated from corresponding divided stack layers of the adjacent divided light emitting stacks.

In addition, as the light emitting stack ILL is divided into the first divided light emitting stack ILL1, the second divided light emitting stack ILL2, and the third divided light emitting stack ILL3 separated from each other for each sub-pixel, the charge generation layers of each light emitting stack ILL may also be separated from each other for each sub-pixel. For example, the charge generation layers of each light emitting stack may be disconnected (or cut) along the spacer SPC so as to be separated for each sub-pixel. For example, the first charge generation layer of the first divided light emitting stack ILL1, the first charge generation layer of the second divided light emitting stack ILL2, and the first charge generation layer of the third divided light emitting stack ILL3 may be separated on (e.g., by) the spacer SPC so as not to be connected to each other. In addition, the second charge generation layer of the first divided light emitting stack ILL1, the second charge generation layer of the second divided light emitting stack ILL2, and the second charge generation layer of the third divided light emitting stack ILL3 may be separated on (e.g., by) the spacer SPC so as not to be connected to each other.

In this way, because the light emitting stack ILL may be disconnected for each sub-pixel (e.g., between neighboring sub-pixels), leakage current (e.g., lateral leakage current) between the adjacent sub-pixels may be minimized or reduced, thereby preventing or reducing a color mixing phenomenon between the adjacent sub-pixels. In addition, if (e.g., when) the light emitting stack is disconnected through an existing trench, leakage current (e.g., vertical leakage current) due to a gap reduction between the charge generation layers within the trench may be minimized or reduced, thereby preventing or mitigating a reduction (decrease) in light efficiency. For example, because the spacer does not generate voids as occurs in the existing trench, a problem of vertical leakage current due to the gap reduction between the charge generation layers at the ends of the voids may be solved.

The second electrode CAT may be arranged on the light emitting stack ILL. The second electrode CAT may include a semi-transmissive conductive material such as magnesium (Mg), silver (Ag), or an alloy of magnesium (Mg) and silver (Ag). In this regard, light emission efficiency may be increased in each of the first to third sub-pixels SP1, SP2, and SP3 by micro cavities.

The second electrode CAT may be disconnected on the spacer SPC to be separated for each sub-pixel. For example, in one or more embodiments, the second electrode CAT may include a first divided electrode CAT1 overlapping the first light emitting area EA1 of the first sub-pixel SP1, a second divided electrode CAT2 overlapping the second light emitting area EA2 of the second sub-pixel SP2, and a third divided electrode CAT3 overlapping the third light emitting area EA3 of the third sub-pixel SP3. Here, the first divided electrode CAT1 of the first sub-pixel SP1, the second divided electrode CAT2 of the second sub-pixel SP2, and the third divided electrode CAT3 of the third sub-pixel SP3 may be separated on the spacer SPC so as not to be connected to each other. The first divided electrode CAT1 may be connected to the first divided light emitting stack ILL1, the second divided electrode CAT2 may be connected to the second divided light emitting stack ILL2, and the third divided electrode CAT3 may be connected to the third divided light emitting stack ILL3. The first divided electrode CAT1, the second divided electrode CAT2, and the third divided electrode CAT3 may be respectively arranged on the light emitting stack ILL so as to overlap the side surface of the spacer SPC. The first divided electrode CAT1, the second divided electrode CAT2, and the third divided electrode CAT3 are not arranged on the upper surface of the spacer SPC. For example, the first divided electrode CAT1, the second divided electrode CAT2, and the third divided electrode CAT3 may not overlap the upper surface of the spacer SPC.

The encapsulation layer TFE may be arranged on the display element layer EML. The encapsulation layer TFE may include at least one encapsulation layer to prevent or reduce oxygen and/or moisture from permeating into the display element layer EML. For example, in one or more embodiments, the encapsulation layer TFE may include a first encapsulation layer TFE1, a second encapsulation layer TFE2, a third encapsulation layer TFE3, and a fourth encapsulation layer TFE4 sequentially stacked on the display element layer along the third direction.

The first encapsulation layer TFE1 may be arranged on the second electrode CAT. In one or more embodiments, the first encapsulation layer TFE1 may be made of a material including silicon oxide (SiO₂). The first encapsulation layer TFE1 may be disconnected on (e.g., by) the spacer SPC to be separated for each sub-pixel. For example, the first encapsulation layer TFE1 may include a first divided encapsulation layer TF1 overlapping the first light emitting area EA1 of the first sub-pixel SP1, a second divided encapsulation layer TF2 overlapping the second light emitting area EA2 of the second sub-pixel SP2, and a third divided encapsulation layer TF3 overlapping the third light emitting area EA3 of the third sub-pixel SP3. Here, the first divided encapsulation layer TF1 of the first sub-pixel SP1, the second divided encapsulation layer TF2 of the second sub-pixel SP2, and the third divided encapsulation layer TF3 of the third sub-pixel SP3 may be separated on the spacer SPC so as not to be connected to each other. The first divided encapsulation layer TF1, the second divided encapsulation layer TF2, and the third divided encapsulation layer TF3 may be respectively arranged on the second electrode CAT so as to overlap the side surface of the spacer SPC. The first divided encapsulation layer TF1, the second divided encapsulation layer TF2, and the third divided encapsulation layer TF3 are not arranged on the upper surface of the spacer SPC. The first divided encapsulation layer TF1, the second divided encapsulation layer TF2, and the third divided encapsulation layer TF3 do not overlap the upper surface of the spacer SPC.

The second encapsulation layer TFE2 may be arranged on the first encapsulation layer TFE1 and the spacer SPC. In addition, the second encapsulation layer TFE2 may be arranged on an end of the light emitting stack ILL (e.g., a cut surface of the light emitting stack ILL). The second encapsulation layer TFE2 may be in contact with the end of the light emitting stack ILL (e.g., the cut surface of the light emitting stack ILL). In one or more embodiments, the second encapsulation layer TFE2 may be made of a material including silicon oxide (SiO₂). In this regard, the second encapsulation layer TFE2 may be formed by an atomic layer deposition (ALD) process. The second encapsulation layer TFE2 may be smaller than or equal to about 100 nm.

The third encapsulation layer TFE3 may be arranged on the second encapsulation layer TFE2. The third encapsulation layer TFE3 may be arranged on the second encapsulation layer TFE2 so as to overlap the spacer SPC. The third encapsulation layer TFE3 may be connected to (or in contact with or in direct contact with) (e.g., electrically connected to) the second electrode CAT. For example, the third encapsulation layer TFE3 may be connected to (e.g., electrically connected to) the first divided electrode CAT1, the second divided electrode CAT2, and the third divided electrode CAT3, respectively, through a plurality of holes HL penetrating through the second encapsulation layer TFE2 and the first encapsulation layer TFE1. Accordingly, the second electrodes CAT that are disconnected for each sub-pixel may be electrically connected to (or in contact with or in direct contact with) each other by the third encapsulation layer TFE3. For example, the third encapsulation layer TFE3 may serve as an auxiliary electrode (or auxiliary cathode electrode) that electrically connects the first divided electrode CAT1, the second divided electrode CAT2, and the third divided electrode CAT3, which are separated from each other. To this end, according to one or more embodiments, the third encapsulation layer TFE3 may include a same material as the second electrode CAT. For example, the third encapsulation layer TFE3 may be made of a material including a transparent conductive oxide. For example, in one or more embodiments, the third encapsulation layer TFE3 may be made of a material including Indium Tin Oxide (ITO) or Indium Zinc Oxide (IZO). However, the material of the third encapsulation layer TFE3 is not limited thereto.

The plurality of holes HL may overlap the plurality of light emitting areas EA1 to EA3, respectively. For example, a hole HL penetrating through the second encapsulation layer TFE2 and the first divided encapsulation layer TF1 may overlap the first light emitting area EA1, a hole HL penetrating through the second encapsulation layer TFE2 and the second divided encapsulation layer TF2 may overlap the second light emitting area EA2, and a hole HL penetrating through the second encapsulation layer TFE2 and the third divided encapsulation layer TF3 may overlap the third light emitting area EA3. The plurality of holes HL may be respectively arranged within the light emitting areas EA1 to EA3. For example, in plan view, the hole HL penetrating through the second encapsulation layer TFE2 and the first divided encapsulation layer TF1 may be surrounded by the first light emitting area EA1, the hole HL penetrating through the second encapsulation layer TFE2 and the second divided encapsulation layer TF2 may be surrounded by the second light emitting area EA2, and the hole HL penetrating through the second encapsulation layer TFE2 and the third divided encapsulation layer TF3 may be surrounded by the third light emitting area EA3.

The fourth encapsulation layer TFE4 may be arranged on the third encapsulation layer TFE3. The fourth encapsulation layer TFE4 may be arranged on the third encapsulation layer TFE3 so as to overlap the spacer SPC. The fourth encapsulation layer TFE4 may have the largest thickness among the first to fourth encapsulation layers TFE1 to TFE4. In one or more embodiments, the fourth encapsulation layer TFE4 may be made of a material including silicon oxide (SiO₂).

An organic layer APL may be a layer arranged between the encapsulation layer TFE and the optical layer OPL for increasing an interfacial adhesion between the encapsulation layer TFE and the optical layer OPL. The organic layer APL may be an organic film made of an acryl resin, an epoxy resin, a phenolic resin, a polyamide resin, a polyimide resin, and/or the like.

The optical layer OPL may include a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be arranged on the organic layer APL.

The first color filter CF1 may overlap the first light emitting area EA1 of the first sub-pixel SP1. The first color filter CF1 may be to transmit first light (e.g., light of a green wavelength band). Therefore, the first color filter CF1 may be to transmit the first light among light emitted from the light emitting stack ILL of the first light emitting area EA1.

The second color filter CF2 may overlap the second light emitting area EA2 of the second sub-pixel SP2. The second color filter CF2 may be to transmit second light (e.g., light of a blue wavelength band). Therefore, the second color filter CF2 may be to transmit the second light among light emitted from the light emitting stack ILL of the second light emitting area EA2.

The third color filter CF3 may overlap the third light emitting area EA3 of the third sub-pixel SP3. The third color filter CF3 may be to transmit third light (e.g., light of a red wavelength band). Therefore, the third color filter CF3 may be to transmit the third light among light emitted from the light emitting stack ILL of the third light emitting area EA3.

Each of the plurality of lenses LNS may be arranged on a corresponding one of the first color filter CF1, the second color filter CF2, and the third color filter CF3. Each of the plurality of lenses LNS may be a structure for increasing a ratio of light directed to the front of the display device 10. It is illustrated that each of the plurality of lenses LNS has a cross-sectional shape that is convex in an upward direction, but embodiments of the present disclosure are not limited thereto.

The filling layer FIL may be arranged on the plurality of lenses LNS. The filling layer FIL may have a refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, a polyimide resin, and/or the like.

The cover layer CVL may be arranged on the filling layer FIL. The cover layer CVL may be a glass substrate or a polymer resin such as a resin. In one or more embodiments, when the cover layer CVL is a glass substrate, the cover layer CVL may be attached onto the filling layer FIL. In this regard, the filling layer FIL may serve to attach the cover layer CVL. When the cover layer CVL is a glass substrate, the cover layer CVL may serve as an encapsulation substrate. In one or more embodiments, when the cover layer CVL is a polymer resin such as a resin, the cover layer CVL may be directly applied onto the filling layer FIL.

The polarizing plate POL may be arranged on a (e.g., one) surface of the cover layer CVL. The polarizing plate POL may be a structure for preventing or reducing deterioration in visibility due to reflection of external light. In one or more embodiments, the polarizing plate POL may include a linear polarizing plate and a phase retardation film. For example, the phase retardation film may be a λ/4 (quarter-wave) plate, but embodiments of the present disclosure are not limited thereto. In one or more embodiments, if (e.g., when) the deterioration in visibility due to the reflection of external light is sufficiently reduced by the first to third color filters CF1, CF2, and CF3, the polarizing plate POL may also not be provided.

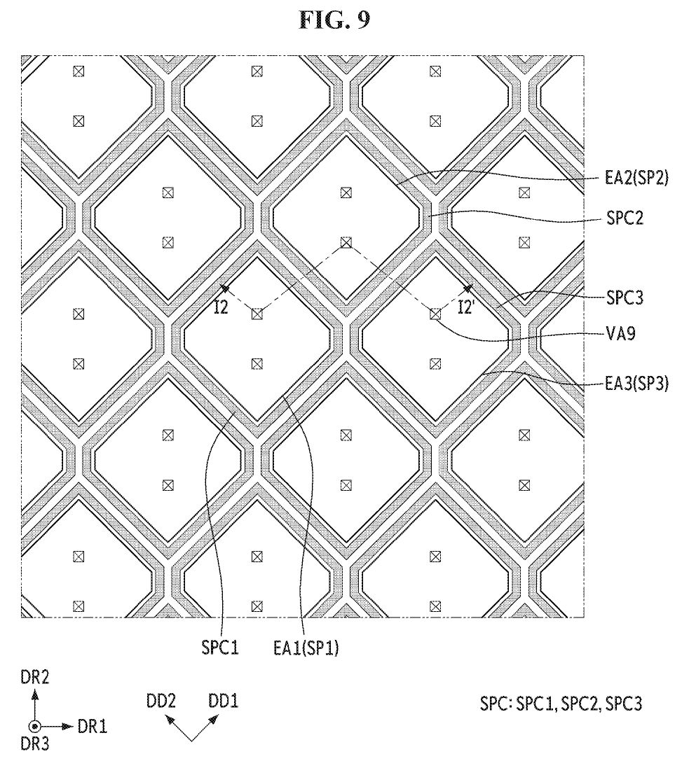

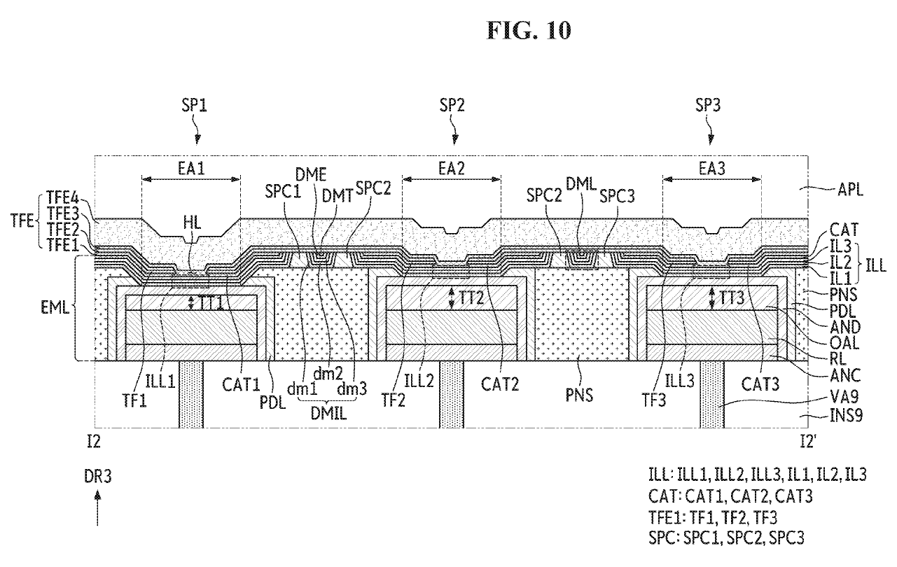

FIG. 9 is a layout diagram illustrating another example of the display area of FIG. 4 according to one or more embodiments of the present disclosure, and FIG. 10 is a cross-sectional view illustrating an example of the display panel taken along the line I2-I2’ of FIG. 9 according to one or more embodiments.

The display area DAA of the display device 10 illustrated in FIG. 9 and FIG. 10 has a difference from the display area DAA of the display device 10 of FIG. 5 described above in a shape of a spacer SPC. The difference will be specifically described as follows.

As illustrated in FIG. 9, the spacer SPC may include a plurality of spacers SPC1, SPC2, and SPC3. For example, the spacer SPC may include a first spacer SPC1 around (e.g., surrounding) the first light emitting area EA1, a second spacer SPC2 around (e.g., surrounding) the second light emitting area EA2, and a third spacer SPC3 around (e.g., surrounding) the third light emitting area EA3.

The first spacer SPC1, the second spacer SPC2, and the third spacer SPC3 may have a same planar shape as the first light emitting area EA1, the second light emitting area EA2, and the third light emitting area EA3, respectively. For example, in plan view, the first spacer SPC1, the second spacer SPC2, and the third spacer SPC3 may each have a hexagonal shape.

The first spacer SPC1, the second spacer SPC2, and the third spacer SPC3 may each be arranged on the planarization layer PNS. For example, the first spacer SPC1, the second spacer SPC2, and the third spacer SPC3 may be spaced and/or apart (e.g., spaced apart or separated) from each other and arranged on the planarization layer PNS.

A dummy layer DML may be arranged between the spacers SPC adjacent to each other. For example, as illustrated in FIG. 10, the dummy layer DML may each be arranged between the first spacer SPC1 and the second spacer SPC2 adjacent to each other, between the first spacer SPC1 and the third spacer SPC3 adjacent to each other, and between the second spacer SPC2 and the third spacer SPC3 adjacent to each other.

As illustrated in FIG. 10, the dummy layer DML may be surrounded by two adjacent spacers SPC, the planarization layer PNS, and the second encapsulation layer TFE2. The dummy layer DML is not connected to the first electrodes AND, the light emitting stack ILL, the second electrode CAT, and the third encapsulation layer TFE3.

The dummy layer DML may include a dummy light emitting stack DMIL, a dummy electrode DME, and a dummy encapsulation layer DMT, as illustrated in FIG. 10.

The dummy light emitting stack DMIL may be arranged on the planarization layer PNS. The dummy light emitting stack DMIL may include a same material as the light emitting stack ILL.

The dummy electrode DME may be arranged on the dummy light emitting stack DMIL. The dummy electrode DME may include a same material as the second electrode CAT.

The dummy encapsulation layer DMT may be arranged on the dummy electrode DME. The dummy encapsulation layer DMT may include a same material as the first encapsulation layer TFE1.

The above-described dummy light emitting stack DMIL may include a first dummy stack layer dm1, a second dummy stack layer dm2, and a third dummy stack layer dm3.

The first dummy stack layer dm1 may be arranged on the planarization layer PNS. The first dummy stack layer dm1 may include a same material as the first stack layer IL1.

The second dummy stack layer dm2 may be arranged on the first dummy stack layer dm1. The second dummy stack layer dm2 may include a same material as the second stack layer IL2.

The third dummy stack layer dm3 may be arranged on the second dummy stack layer dm2. The third dummy stack layer dm3 may include a same material as the third stack layer IL3.

The dummy layer DML may further include a first dummy charge generation layer including a same material as the first charge generation layer described above and a second dummy charge generation layer including a same material as the second charge generation layer described above. The first dummy charge generation layer may be arranged between the first dummy stack layer dm1 and the second dummy stack layer dm2, and the second dummy charge generation layer may be arranged between the second dummy stack layer dm2 and the third dummy stack layer dm3.

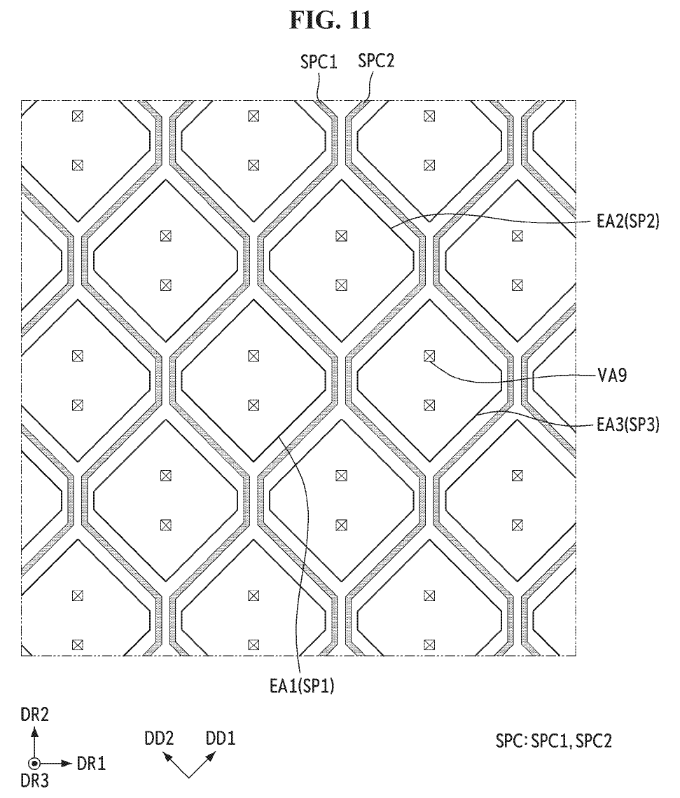

FIG. 11 is a layout diagram illustrating an example of the display area of FIG. 4 according to one or more embodiments of the present disclosure.

The display area DAA of the display device 10 illustrated in FIG. 11 has a difference from the display area DAA of the display device 10 of FIG. 5 described above in a shape of a spacer SPC. The difference will be specifically described as follows.

As illustrated in FIG. 11, the spacer SPC may include a plurality of spacers SPC1 and SPC2. For example, the spacer SPC may include a first spacer SPC1 arranged between the first light emitting area EA1 and the second light emitting area EA2 adjacent to each other, and a second spacer SPC2 arranged between the second light emitting area EA2 and the third light emitting area EA3 adjacent to each other.

For example, if (e.g., when) a plurality of first light emitting areas EA1 arranged in a row along the second direction DR2 and providing light of the same color (e.g., a first color) is defined as a first group light emitting area, a plurality of second light emitting areas EA2 arranged in a row along the second direction DR2 and providing light of the same color (e.g., a second color) is defined as a second group light emitting area, and a plurality of third light emitting areas EA3 arranged in a row along the second direction DR2 and providing light of the same color (e.g., a third color) is defined as a third group light emitting area, the first spacer SPC1 may be arranged between the first group light emitting area and the second group light emitting area adjacent to each other in the first direction DR1, and the second spacer SPC2 may be arranged between the second group light emitting area and the third group light emitting area adjacent to each other in the first direction DR1.

The first spacer SPC1 may extend along the second direction DR2. The first spacer SPC1 may have a curved shape. For example, in one or more embodiments, the first spacer SPC1 may have a zig-zag shape.

The second spacer SPC2 may be adjacent to the first spacer SPC1 in the first direction DR1. The second spacer SPC2 may extend along the second direction DR2. The second spacer SPC2 may have a curved shape. For example, in one or more embodiments, the second spacer SPC2 may have a zig-zag shape.

A group light emitting area may be arranged between the first spacer SPC1 and the second spacer SPC2 adjacent to each other.

Because the light emitting stack ILL is disconnected between the first group light emitting area and the second group light emitting area by the first spacer SPC1, light of the first group light emitting area and light of the second group light emitting area may be prevented or reduced from being mixed with each other.

Because the light emitting stack ILL is disconnected between the second group light emitting area and the third group light emitting area by the second spacer SPC2, the light of the second group light emitting area and light of the third group light emitting area may be prevented or reduced from being mixed with each other.

Because no spacer SPC is arranged between the light emitting areas within the same light emitting group, the light emitting stack ILL and the second electrode CAT between the light emitting areas within the same light emitting group may be connected to each other without being disconnected. Because the light emitting areas within the same light emitting group emit light of the same color, color mixing between the light emitting areas within the same light emitting group does not significantly affect deterioration in an image quality.

The encapsulation layer TFE of the display device 10 illustrated in FIG. 11 may not include (e.g., may exclude) the third encapsulation layer TFE3 as described above. For example, as illustrated in FIG. 11, when the spacer SPC is not arranged between the light emitting areas emitting light of the same color, the second electrode CAT between the light emitting areas within one light emitting group is not disconnected. Therefore, the third encapsulation layer TFE3 that serves as the auxiliary electrode for connecting the second electrode CAT may not be provided. For example, the cross-sectional view of the display device 10 of FIG. 11 may be substantially the same as the cross-sectional view of the display device in which the third encapsulation layer TFE3 is omitted in FIG. 6 and FIG. 7.

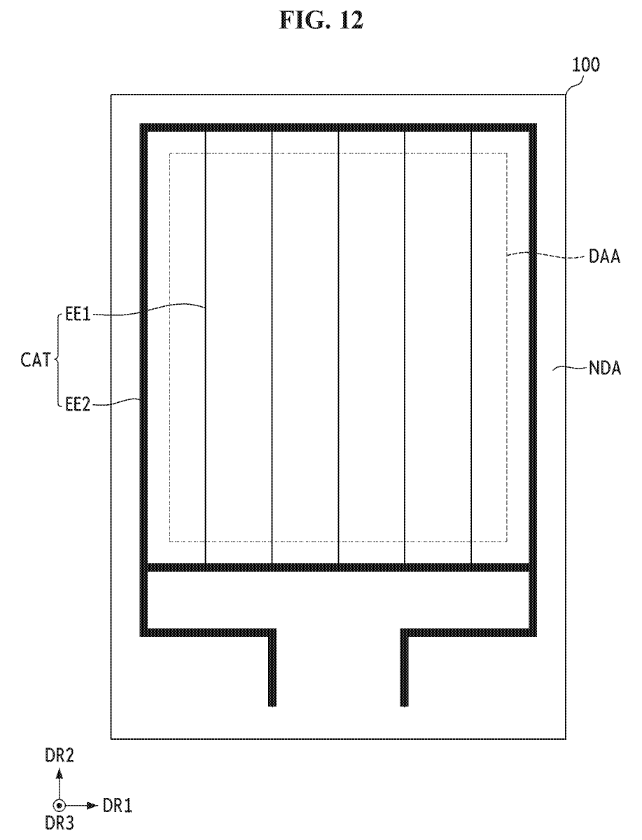

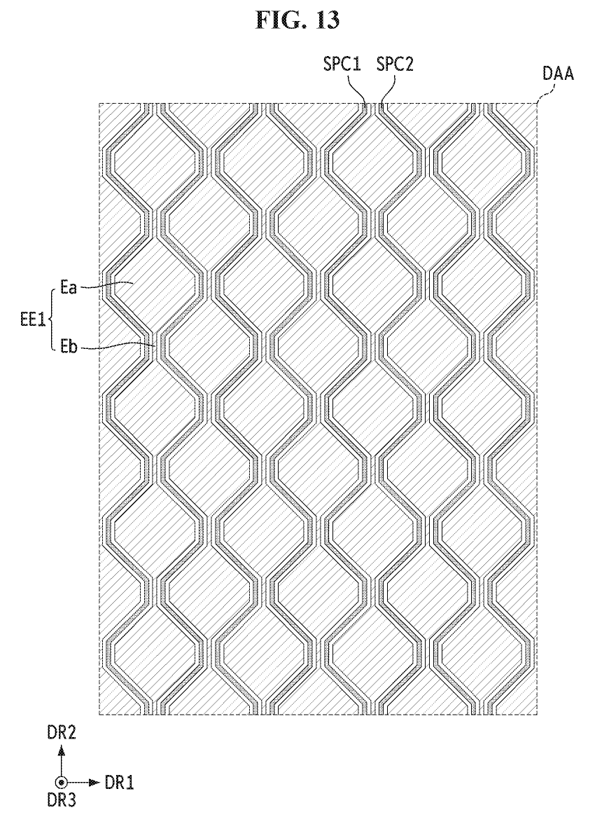

An example shape of the second electrode CAT illustrated in FIG. 11 will be described in more detail with reference to FIG. 12 and FIG. 13 as follows.

FIG. 12 is a schematic diagram of a second electrode of FIG. 11 according to one or more embodiments of the present disclosure, and FIG. 13 is an enlarged view of a portion of the display area of FIG. 11 according to one or more embodiments.

As illustrated in FIG. 12, the second electrode CAT may include an inner electrode EE1 positioned in the display area DAA and an outer electrode EE2 arranged outside the display area DAA (e.g., in the non-display area NDA).

A plurality of inner electrodes EE1 may each extend along the second direction DR2. The plurality of inner electrodes EE1 may be connected to outer electrodes EE2.

The outer electrode EE2 may have a shape around (e.g., surrounding) the display area DAA. A width of the outer electrode EE2 may be greater than a width of the inner electrode EE1.

As illustrated in FIG. 13, in plan view, the inner electrode EE1 may be arranged between the first spacer SPC1 and the second spacer SPC2.

The inner electrode EE1 may include a planar electrode Ea and a linear electrode Eb.

The planar electrode Ea may overlap the light emitting area. The planar electrode Ea may have a greater area than the linear electrode Eb.

The linear electrode Eb may be arranged between the planar electrodes Ea adjacent to each other in the second direction DR2. The linear electrode Eb may connect the planar electrodes Ea adjacent to each other in the second direction DR2. The planar electrode Ea and the linear electrode Eb connected to each other may be integrally formed.

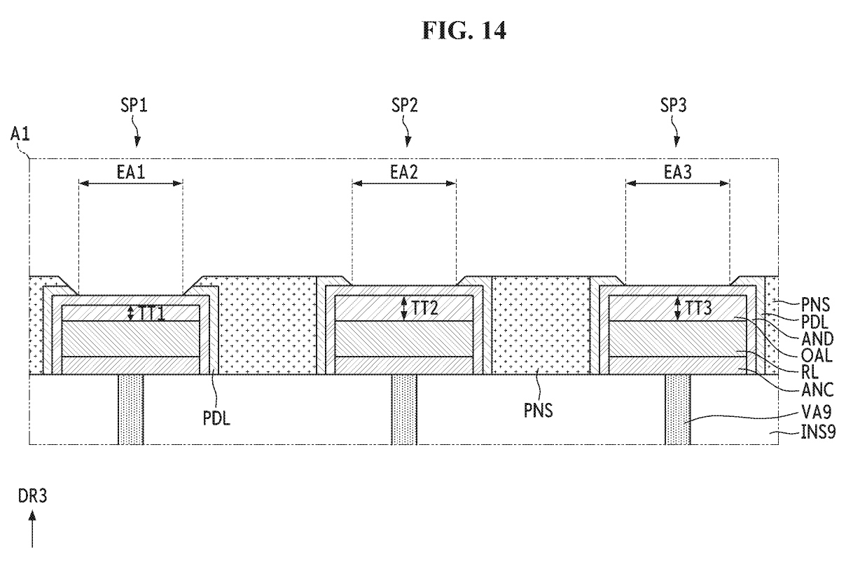

FIGS. 14, 15, 16, 17, 18, 19, 20, and FIG. 21 are process cross-sectional views for describing a method for fabricating a display device according to one or more embodiments of the present disclosure. For example, FIGS. 14 to 21 may be process cross-sectional views for describing a method for fabricating the display device of FIG. 7 according to one or more embodiments.

First, as illustrated in FIG. 14, after a ninth insulating layer INS9 may be formed on a substrate (e.g., a semiconductor substrate SSUB), ninth via layers VA9 penetrating through the ninth insulating layer INS9 may be formed. Next, connection electrodes ANC may each be formed on the ninth via layers VA9, reflective electrodes RL may each be formed on the connection electrodes ANC, optical auxiliary layers OAL may each be formed on the reflective electrodes RL, and first electrodes AND may each be formed on the optical auxiliary layers OAL. Thereafter, a pixel defining layer PDL covering an edge of each of the first electrodes AND may be formed, and a planarization layer PNS may be formed on the pixel defining layer PDL. A first light emitting area EA1 of a first sub-pixel SP1, a second light emitting area EA2 of a second sub-pixel SP2, and a third light emitting area EA3 of a third sub-pixel SP3 may be formed by the pixel defining layer PDL.

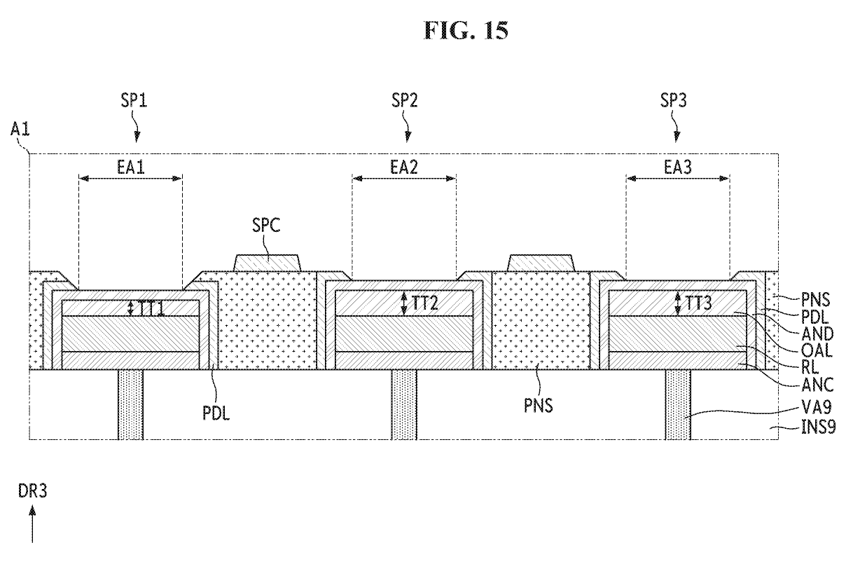

Next, as illustrated in FIG. 15, a spacer SPC may be formed on the planarization layer PNS. In one or more embodiments, the spacer SPC may be made of a material including silicon nitride (SiNₓ).

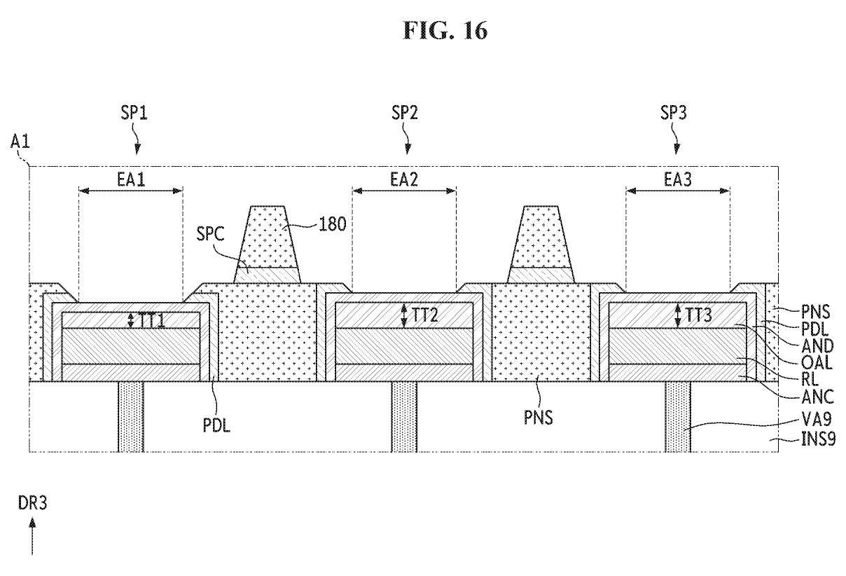

Thereafter, as illustrated in FIG. 16, a sacrificial layer 180 may be formed on the spacer SPC. For example, the sacrificial layer 180 may be formed on the spacer SPC so as to completely cover the spacer SPC. The sacrificial layer 180 may be made of a material different from the spacer SPC. For example, in one or more embodiments, the sacrificial layer 180 may be made of a material including silicon oxide (SiO₂).

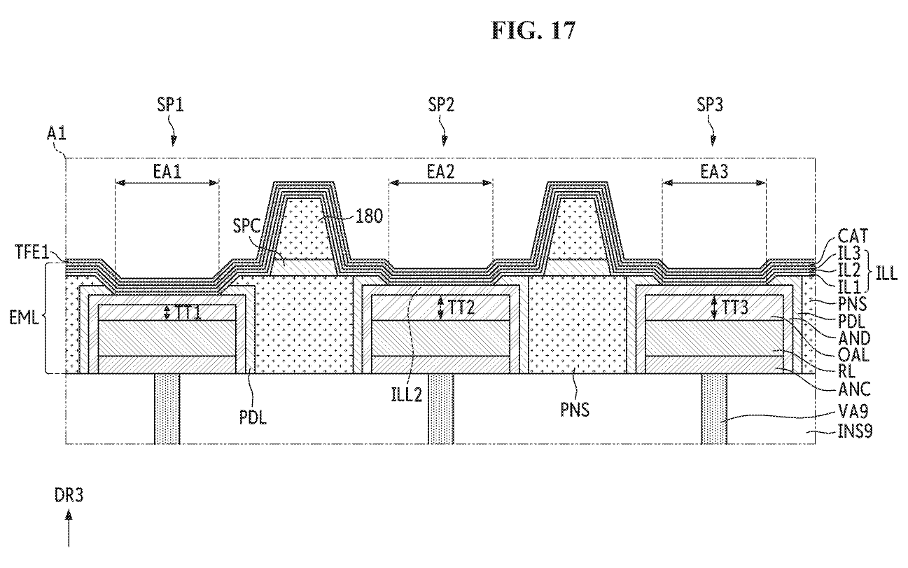

Next, as illustrated in FIG. 17, a light emitting stack ILL may be formed on the first electrodes AND, the pixel defining layer PDL, the planarization layer PNS, and the sacrificial layer 180, a second electrode CAT may be formed on the light emitting stack ILL, and a first encapsulation layer TFE1 may be formed on the second electrode CAT. Here, the light emitting stack ILL, the second electrode CAT, and the first encapsulation layer TFE1 may be arranged on upper and side surfaces of the spacer SPC. The light emitting stack ILL may include a first stack layer IL1, a second stack layer IL2, and a third stack layer IL3. In this regard, the first stack layer IL1 may be formed on the first electrodes AND, the pixel defining layer PDL, the planarization layer PNS, and the sacrificial layer 180, and then the second stack layer IL2 may be formed on the first stack layer IL1, and then the third stack layer IL3 may be formed on the second stack layer IL2.

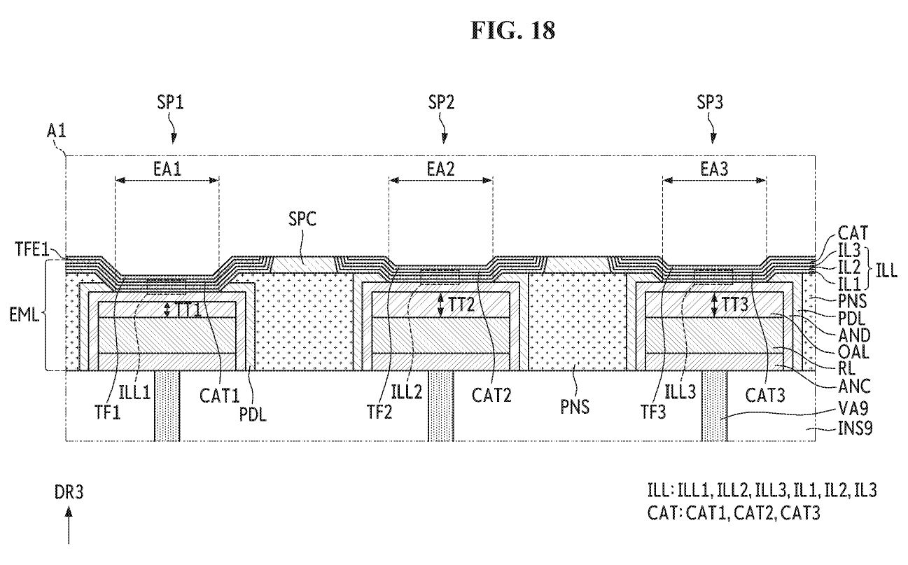

Thereafter, as illustrated in FIG. 18, the sacrificial layer 180 may be removed. For example, the sacrificial layer 180 may be removed through chemical mechanical polishing (CMP). In this regard, the spacer SPC may be used as an etch stopper during the chemical mechanical polishing. As the sacrificial layer 180 is removed, the light emitting stack ILL, the second electrode CAT, and the first encapsulation layer TFE1 on upper and side surfaces of the sacrificial layer 180 may be removed. Accordingly, the light emitting stack ILL, the second electrode CAT, and the first encapsulation layer TFE1 may each have a shape disconnected along the spacer SPC. For example, as the sacrificial layer 180 is removed, the light emitting stack ILL may include a first divided light emitting stack ILL1, a second divided light emitting stack ILL2, and a third divided light emitting stack ILL3 separated from each other for each sub-pixel, the second electrode CAT may include a first divided electrode CAT1, a second divided electrode CAT2, and a third divided electrode CAT3 separated from each other for each sub-pixel, and the first encapsulation layer TFE1 may include a first divided encapsulation layer TF1, a second divided encapsulation layer TF2, and a third divided encapsulation layer TF3 separated from each other by each sub-pixel.

The first divided light emitting stack ILL1 may be formed on the first electrode AND of the first sub-pixel SP1, the second divided light emitting stack ILL2 may be formed on the first electrode AND of the second sub-pixel SP2, and the third divided light emitting stack ILL3 may be formed on the first electrode AND of the third sub-pixel SP3, the first divided electrode CAT1 may be formed on the first divided light emitting stack ILL1, the second divided electrode CAT2 may be formed on the second divided light emitting stack ILL2, and the third divided electrode CAT3 may be formed on the third divided light emitting stack ILL3, and the first divided encapsulation layer TF1 may be formed on the first divided electrode CAT1, the second divided encapsulation layer TF2 may be formed on the second divided electrode CAT2, and the third divided encapsulation layer TF3 may be formed on the third divided electrode CAT3.

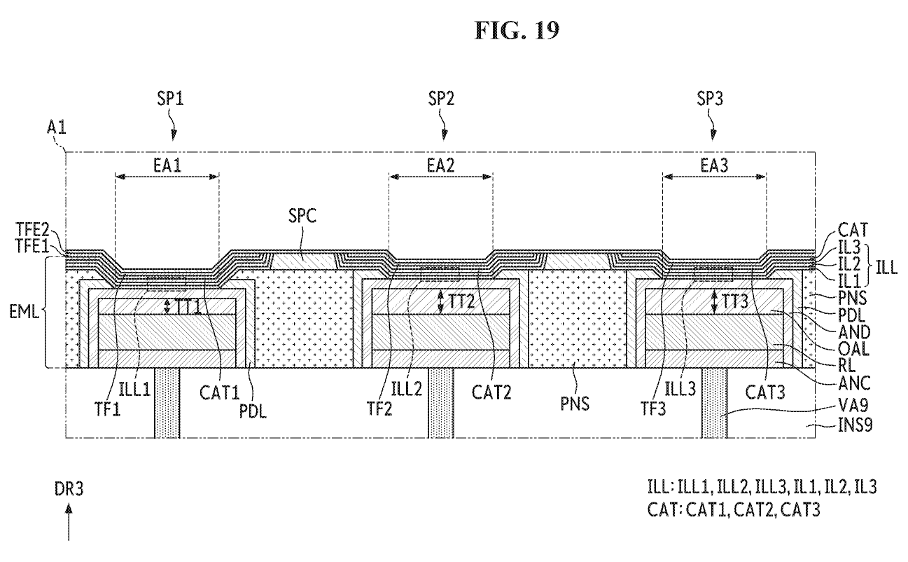

Next, as illustrated in FIG. 19, a second encapsulation layer TFE2 may be formed on the disconnected first encapsulation layer TFE1 (e.g., the first divided encapsulation layer TF1, the second divided encapsulation layer TF2, and the third divided encapsulation layer TF3), the spacer SPC, a cut surface of the first encapsulation layer TFE1, a cut surface of the second electrode CAT, and a cut surface of the light emitting stack ILL.

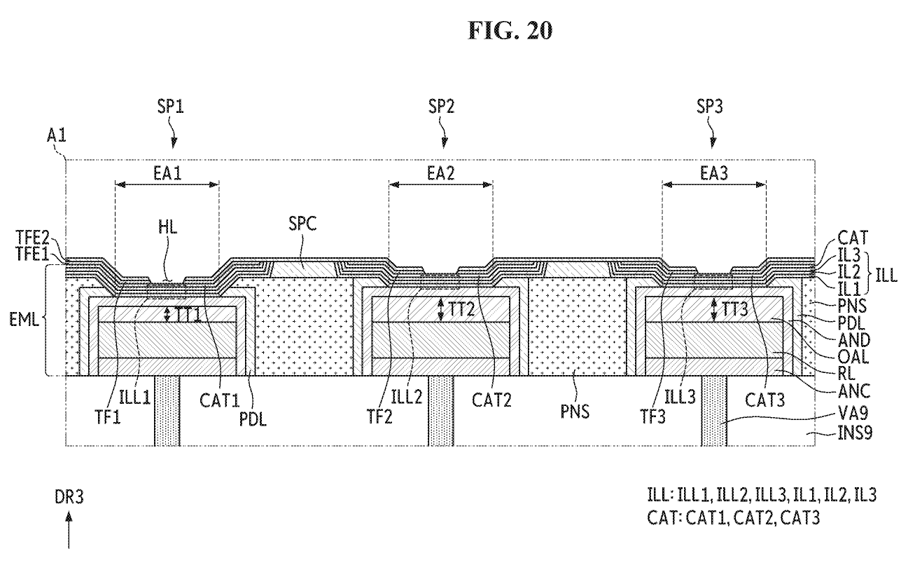

Next, as illustrated in FIG. 20, a plurality of holes HL penetrating through the second encapsulation layer TFE2 and the first encapsulation layer TFE1 may be formed. For example, a hole HL exposing the first divided electrode CAT1 by penetrating through the second encapsulation layer TFE2 and the first divided encapsulation layer TF1, a hole HL exposing the second divided electrode CAT2 by penetrating through the second encapsulation layer TFE2 and the second divided encapsulation layer TF2, and a hole HL exposing the third divided electrode CAT3 by penetrating through the second encapsulation layer TFE2 and the third divided encapsulation layer TF3 may be formed.

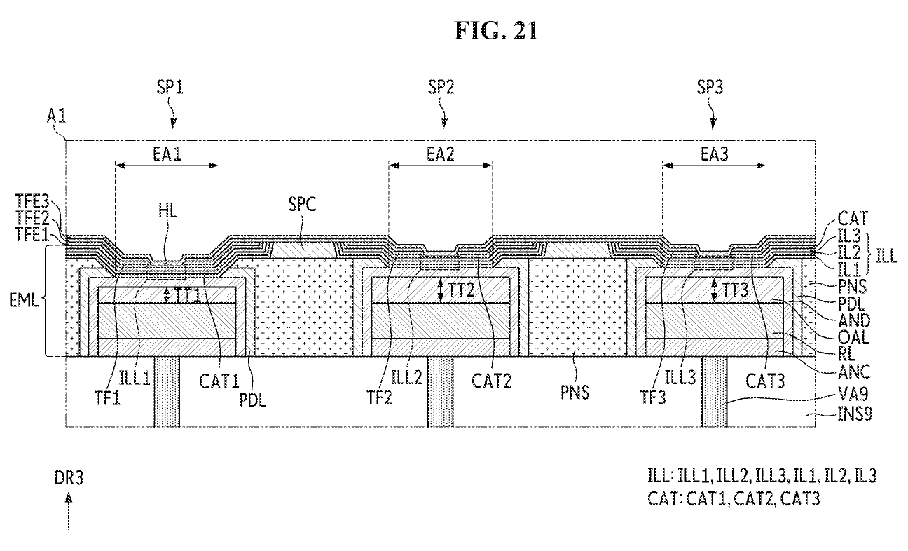

Thereafter, as illustrated in FIG. 21, a third encapsulation layer TFE3 may be formed on the second encapsulation layer TFE2 penetrated by the plurality of holes HL. In this regard, the third encapsulation layer TFE3 may be in contact with the second electrode CAT through the plurality of holes HL. For example, the third encapsulation layer TFE3 may be connected to the first divided electrode CAT1, the second divided electrode CAT2, and the third divided electrode CAT3 through the plurality of holes HL.

Next, as illustrated in FIG. 7, a fourth encapsulation layer TFE4 may be formed on the third encapsulation layer TFE3, and an organic layer APL may be formed on the fourth encapsulation layer TFE4.

Thereafter, as illustrated in FIG. 6, a first color filter CF1, a second color filter CF2, and a third color filter CF3 may be formed on the organic layer APL, a plurality of lenses LNS may be formed on the color filters CF1, CF2, and CF3, a filling layer FIL may be formed on the plurality of lenses LNS, a cover layer CVL may be formed on the filling layer FIL, and a polarizing plate POL may be formed on the cover layer CVL.

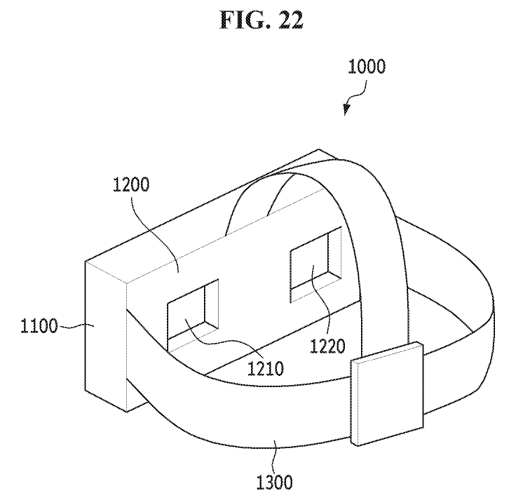

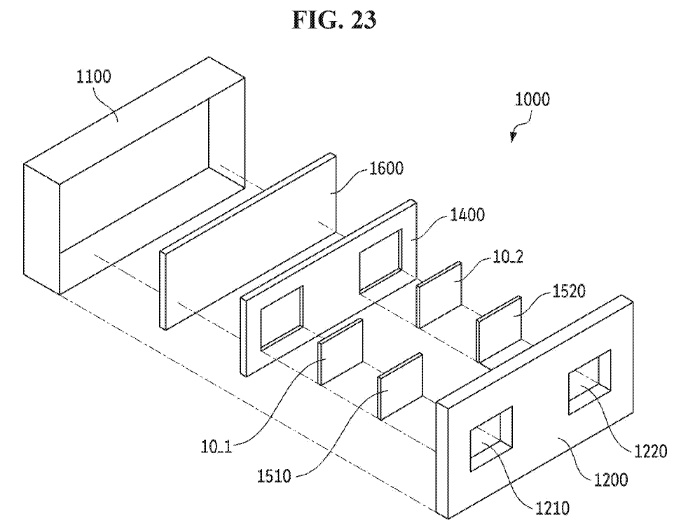

FIG. 22 is a perspective view illustrating a head mounted display device according to one or more embodiments of the present disclosure. FIG. 23 is an exploded perspective view illustrating an example of the head mounted display device of FIG. 22 according to one or more embodiments. For example, FIG. 22 and FIG. 23 illustrate a head mounted display device as an example of an optical device.

Referring to FIG. 22 and FIG. 23, a head mounted display device 1000 according to one or more embodiments may include a first display device 10_1, a second display device 10_2, a display device accommodating portion 1100, an accommodating portion cover 1200, a first eyepiece 1210, a second eyepiece 1220, a head mounting band 1300, a middle frame 1400, a first optical member 1510, a second optical member 1520, and a control circuit board 1600.

The first display device 10_1 provides an image to a user’s left eye, and the second display device 10_2 provides an image to a user’s right eye. Because each of the first display device 10_1 and the second display device 10_2 is substantially the same as the display device 10 described with reference to FIGS. 1 to 19, descriptions of the first display device 10_1 and the second display device 10_2 are not repeated for conciseness.

The first optical member 1510 may be arranged between the first display device 10_1 and the first eyepiece 1210. The second optical member 1520 may be arranged between the second display device 10_2 and the second eyepiece 1220. Each of the first optical member 1510 and the second optical member 1520 may include at least one convex lens.

The middle frame 1400 may be arranged between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device accommodating portion 1100. The control circuit board 1600 may be connected to the first display device 10_1 and the second display device 10_2 through a connector. The control circuit board 1600 may convert an image source input from the outside into digital video data DATA, and may be to transmit the digital video data DATA to the first display device 10_1 and the second display device 10_2 through the connector.

In one or more embodiments, the control circuit board 1600 may be to transmit digital video data DATA corresponding to a left eye image improved or optimized for the user’s left eye to the first display device 10_1, and may be to transmit digital video data DATA corresponding to a right eye image improved or optimized for the user’s right eye to the second display device 10_2. In one or more embodiments, the control circuit board 1600 may be to transmit the same digital video data DATA to the first display device 10_1 and the second display device 10_2.

The display device accommodating portion 1100 serves to accommodate the first display device 10_1, the second display device 10_2, the middle frame 1400, the first optical member 1510, the second optical member 1520, and the control circuit board 1600. The accommodating portion cover 1200 is arranged to cover one opened surface of the display device accommodating portion 1100. The accommodating portion cover 1200 may include a first eyepiece 1210 where the user’s left eye is arranged and a second eyepiece 1220 where the user’s right eye is arranged. It is illustrated in FIG. 22 and 23 that the first eyepiece 1210 and the second eyepiece 1220 are separately arranged, but embodiments of the present disclosure are not limited thereto. In one or more embodiments, the first eyepiece 1210 and the second eyepiece 1220 may be integrated into one.

The first eyepiece 1210 may be aligned with the first display device 10_1 and the first optical member 1510, and the second eyepiece 1220 may be aligned with the second display device 10_2 and the second optical member 1520. Therefore, the user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

The head mounting band 1300 serves to fix the display device accommodating portion 1100 to a user’s head so that the first eyepiece 1210 and the second eyepiece 1220 of the accommodating portion cover 1200 are arranged aligned with the user’s left and right eyes, respectively.

In one or more embodiments, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

The display device 10 according to one or more embodiments may be applied to one or more suitable electronic devices. An electronic device according to one or more embodiments may include the display device 10 described above, and may further include a module or a device having additional functions in addition to the display device 10.

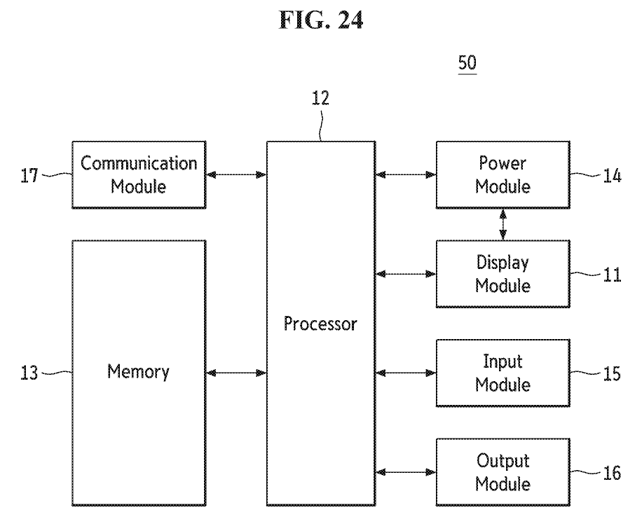

FIG. 24 is a block diagram of an electronic device according to one or more embodiments of the present disclosure. Referring to FIG. 24, an electronic device 50 according to one or more embodiments may include a display module 11, a processor 12, a memory 13, and a power module 14. The electronic device 50 may further include an input module 15, a non-image output module 16, and/or a communication module 17.

The electronic device 50 may output one or more suitable information in the form of an image through the display module 11. When the processor 12 executes an application stored in the memory 13, image information provided by the application may be provided to a user through the display module 11. The power module 14 may include a power supply module, such as a power adapter or a battery device, and a power conversion module that converts power supplied by the power supply module to generate power desired or required for an operation of the electronic device 50. The input module 15 may provide input information to the processor 12 and/or the display module 11. The non-image output module 16 may serve to receive information other than the image transmitted from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In one or more embodiments, some of the individual modules functionally included within one module may be included within the display device, while others may be provided separately from the display device. For example, in one or more embodiments, the display device includes the display module 11, and the processor 12, the memory 13, and the power module 14 may be provided in the form of other devices within the electronic device 50 other than the display device.

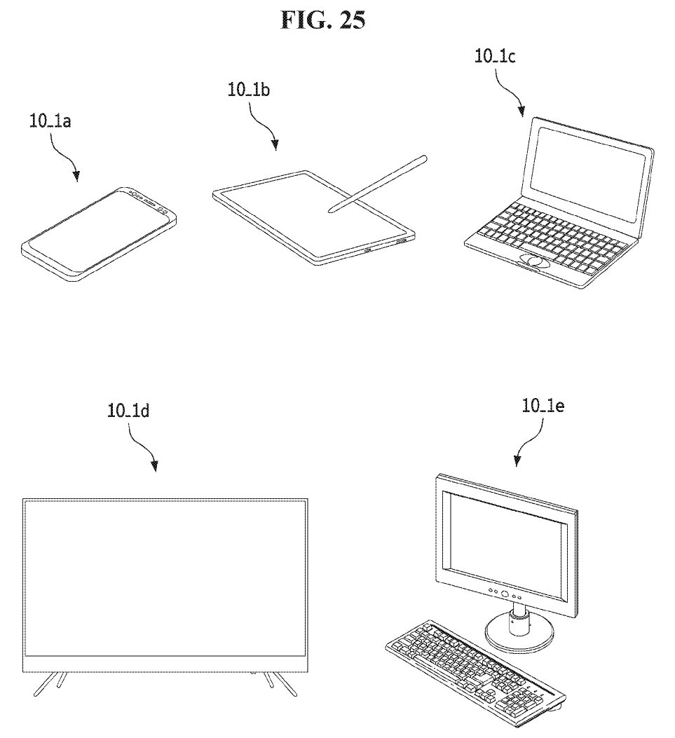

FIGS. 25, 26, and FIG. 27 are schematic diagrams illustrating electronic devices according to one or more embodiments of the present disclosure. FIGS. 25 to 27 illustrate examples of one or more suitable electronic devices to which the display device 10 according to one or more embodiments is applied.

FIG. 25 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e may also include a display module and an input module similarly to the smartphone 10_1a, and in some embodiments, may further include a communication module.

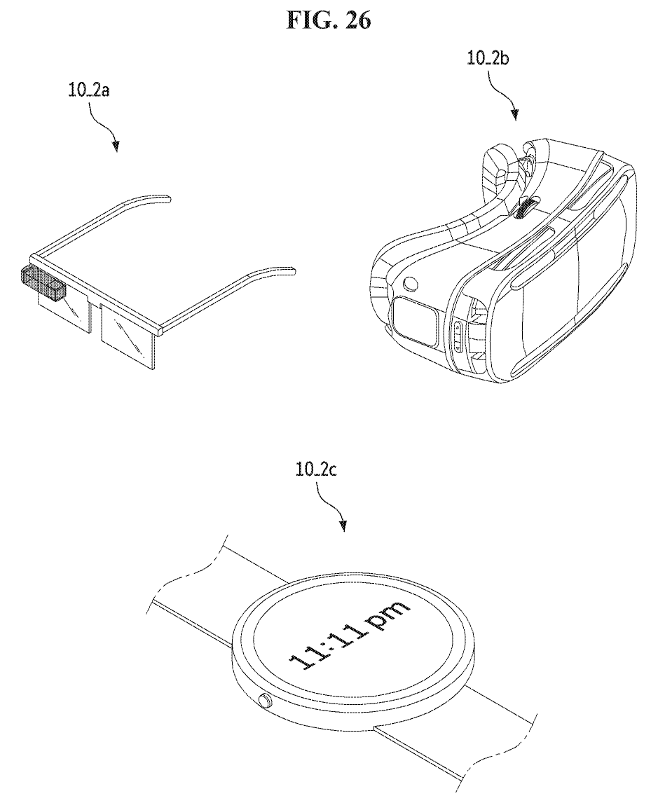

FIG. 26 illustrates embodiments in which an electronic device including a display module is applied to a wearable electronic device. The wearable electronic device may be a smart glasses 10_2a, a head mounted display 10_2b, a smart watch 10_2c, and/or the like.

The smart glasses 10_2a and the head mounted display 10_2b may each include a display module that emits a display image and a reflector that reflects the emitted display image and provides the reflected display image to the user's eyes, and may provide the user with a virtual reality or augmented reality screen through the display module and the reflector.

The smart watch 10_2c may include a biometric sensor as an input device and may provide biometric information recognized by the biometric sensor to the user through the display module.

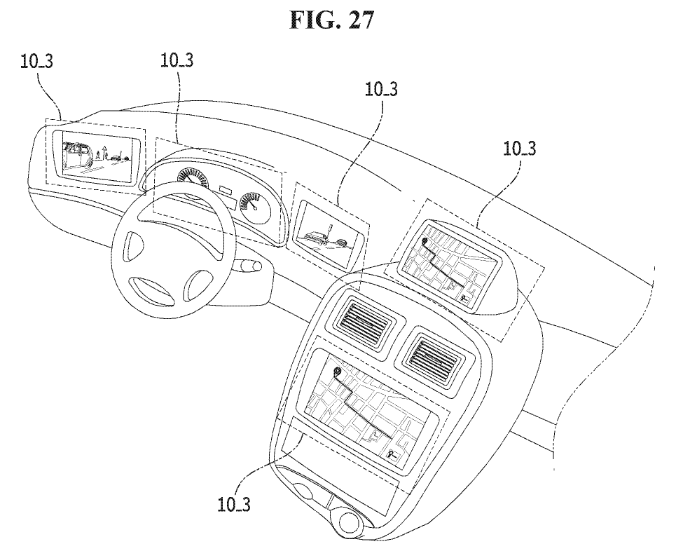

FIG. 27 illustrates an embodiment in which an electronic device including a display module is applied to a vehicle. For example, an electronic device 10_3 may be applied to a dashboard, center fascia, and/or the like of an automobile, or may be applied to a Center Information Display (CID) arranged on a dashboard of the automobile or a room mirror display replacing a side mirror.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure".

In the present disclosure, expressions such as "at least one of," "one of," and "selected from," when preceding a list of elements, modify the entire list of elements and do not modify the individual elements of the list. For example, "at least one of a, b or c", “at least one selected from a, b, and c”, "at least one selected from among a to c", etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms "use," "using," and "used" may be considered synonymous with the terms "utilize," "utilizing," and "utilized," respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display module, the display panel, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with one another, partially or entirely, and may be technically interlocked and operated in various suitable ways, and each embodiment may be implemented independently of one another or in conjunction with one another in any suitable manner unless otherwise stated or implied.

In concluding the detailed description, those skilled in the art will appreciate that many variations and modifications can be made to the described example embodiments without substantially departing from the principles of the present disclosure. Therefore, the disclosed embodiments of the present disclosure are used in a generic and descriptive sense only and not for purposes of limitation. It is further understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device, comprising:
a substrate;
a reflective electrode on the substrate;
an optical auxiliary layer on the reflective electrode;
a first electrode on the optical auxiliary layer;
a light emitting stack on the first electrode;
a second electrode on the light emitting stack;
a pixel defining layer on an edge of the first electrode and defining a light emitting area;
a planarization layer on the pixel defining layer; and
a spacer protruding on the planarization layer,
wherein the light emitting stack is disconnected from a neighboring light emitting stack along the spacer.

2. The display device of claim 1, wherein, in plan view, the spacer is around the light emitting area.

3. The display device of claim 1, wherein the display device comprises a plurality of light emitting areas defined by the pixel defining layer, and
wherein, in plan view, the spacer has a mesh shape that is individually around the plurality of light emitting areas.

4. The display device of claim 1, wherein the display device comprises a plurality of light emitting areas defined by the pixel defining layer and a plurality of spacers, and
wherein, in plan view, the plurality of spacers each is around a corresponding light emitting area among the plurality of light emitting areas.

5. The display device of claim 4, further comprising a dummy layer between adjacent spacers on the planarization layer.

6. The display device of claim 5, wherein a portion of the dummy layer comprises a same material as the light emitting stack.

7. The display device of claim 1, wherein the display device comprises a plurality of light emitting areas defined by the pixel defining layer,
wherein the plurality of light emitting areas comprise:
a plurality of first light emitting areas that is configured to provide light of a first color; and
a plurality of second light emitting areas that is configured to provide light of a second color different from the first color, and
wherein, in plan view, the spacer is between a first group light emitting area comprising the plurality of first light emitting areas and a second group light emitting area comprising the plurality of second light emitting areas.

8. The display device of claim 7, wherein the spacer is not between adjacent first light emitting areas and is not between adjacent second light emitting areas.

9. The display device of claim 1, wherein the second electrode is disconnected from a neighboring second electrode along the spacer.

10. The display device of claim 9, further comprising an encapsulation layer on the second electrode,
wherein a portion of the encapsulation layer is electrically connected to the second electrode.

11. The display device of claim 10, wherein the encapsulation layer comprises a plurality of encapsulation layers sequentially stacked, and
wherein any one among the plurality of encapsulation layers is electrically connected to the second electrode.

12. The display device of claim 11, wherein one among the encapsulation layers is electrically connected to the second electrode through a hole penetrating through intervening encapsulation layers.

13. The display device of claim 12, wherein the hole overlaps the light emitting area.

14. The display device of claim 11, wherein the one among the encapsulation layers electrically connected to the second electrode comprises a same material as the second electrode.

15. The display device of claim 9, further comprising an encapsulation layer on the second electrode,
wherein a portion of the encapsulation layer is disconnected along the spacer.

16. The display device of claim 15, wherein the encapsulation layer comprises a plurality of encapsulation layers sequentially stacked, and
one or more among the plurality of encapsulation layers are disconnected along the spacer.

17. The display device of claim 1, wherein the spacer comprises a same material as the pixel defining layer.

18. An electronic device, comprising:
a display device comprising a screen,
wherein the display device comprises:
a substrate;
a reflective electrode on the substrate;
an optical auxiliary layer on the reflective electrode;
a first electrode on the optical auxiliary layer;
a light emitting stack on the first electrode;
a second electrode on the light emitting stack;
a pixel defining layer on an edge of the first electrode and defining a light emitting area;
a planarization layer on the pixel defining layer; and
a spacer protruding on the planarization layer, and
wherein the light emitting stack is disconnected from a neighboring light emitting stack along the spacer.

19. A method, comprising:
forming a reflective electrode on a substrate;
forming an optical auxiliary layer on the reflective electrode;
forming a first electrode on the optical auxiliary layer;
forming a pixel defining layer defining a light emitting area on an edge of the first electrode;
forming a planarization layer on the pixel defining layer;
forming a spacer on the planarization layer;
forming a sacrificial layer comprising a material different from the spacer on the spacer so as to overlap the spacer;
forming a light emitting stack on the first electrode, the pixel defining layer, the planarization layer, and the sacrificial layer;
forming a second electrode on the light emitting stack;
forming a first encapsulation layer on the second electrode; and
disconnecting the light emitting stack, the second electrode, and the first encapsulation layer on the sacrificial layer along the spacer by removing the sacrificial layer,
wherein the method is a method for fabricating a display device.

20. The method of claim 19, further comprising:
forming a second encapsulation layer on the first encapsulation layer, a cut surface of the first encapsulation layer, the second electrode, a cut surface of the second electrode, the light emitting stack, a cut surface of the light emitting stack, and the spacer;
forming a hole penetrating through the second encapsulation layer and the first encapsulation layer and exposing the second electrode;
forming a third encapsulation layer electrically connected to the second electrode through the hole on the second encapsulation layer; and
forming a fourth encapsulation layer on the third encapsulation layer.
